(19) United States
(12) Patent Application Publication
(10) Pub. No.: US 2015/0064401 A1
(43) Pub. Date: Mar. 5, 2015

(54) GAS BARRIER FILM AND ELECTRONIC DEVICE

(71) Applicant: Konica Minolta, Inc., Tokyo (JP)

(72) Inventor: Makoto Honda, Tokyo (JP)

(21) Appl. No.: 14/389,179

(22) PCT Filed: Apr. 1, 2013
(86) PCT No.: PCT/JP2013/059856

§ 371 Date: Sep. 29, 2014

(30) Foreign Application Priority Data
Apr. 2, 2012 (JP) 2012-083995

(51) Int. Cl. H01L 51/52

(52) U.S. Cl. CPC H01L 51/5246
USPC 428/141; 428/447; 428/331

(57) ABSTRACT

The present invention relates to a gas barrier film having a first gas barrier layer formed by irradiating a polysilazane-containing layer with a vacuum ultraviolet ray, a second gas barrier layer formed by irradiating a polysilazane-containing layer with a vacuum ultraviolet ray, and a hydrophobic intermediate layer disposed between the first gas barrier layer and the second gas barrier layer and containing a metal compound particle. The invention can provide a gas barrier film having extremely excellent gas barrier property and durability and good productivity.

### TECHNICAL FIELD

The present invention relates to a gas barrier film and an electronic device, and relates more specifically to a gas barrier film, which is mainly used for an electronic device such as an organic electroluminescence (EL) element, a solar cell element, or a liquid crystal display element, and an electronic device using the gas barrier film.

### BACKGROUND ART

Conventionally, a gas barrier film produced by laminating plural layers including a thin film of metallic oxide such as aluminum oxide, magnesium oxide, or silicon oxide on the surface of a plastic substrate or a film has been extensively used to package the products that require blocking of various types of gases such as water vapor and oxygen, for example, for packaging purposes to package the foods, industrial products, and pharmaceutical products to prevent them from being deteriorated.

In addition to packaging purposes, development into a flexible electronic device such as a solar cell element, an organic electroluminescence (EL) element, or a liquid crystal display element having flexibility is required, and thus various studies are made. However, since those flexible electronic devices are required to have a gas barrier property that is at the same high level as a glass substrate, in the present moment, a gas barrier film with satisfying performance has not been obtained yet.

As a method of forming those gas barrier films, a vapor phase method as follows is known: a chemical vapor deposition method (CVD method) for forming a film on a substrate with oxidation using oxygen plasma under reduced pressure by using an organosilicon compound represented by tetraethoxysilane (TEOS), and a physical vapor deposition method (vacuum vapor deposition or sputtering method) including evaporating metal Si by using a semiconductor laser and depositing the evaporated metal Si on a substrate in the presence of oxygen.

An inorganic film forming method based on those vapor phase methods has been preferably applied for forming an inorganic film such as silicon oxide, silicon nitride, or silicon oxynitride, and although various studies have been made regarding a composition range of an inorganic film for obtaining a good gas barrier property and also regarding a layer configuration containing these inorganic films, specifying the composition range or layer configuration for having particularly good gas barrier property has not been achieved yet.

Further, it is extremely difficult to form a defect-free film by the vapor phase method described above. For example, since it is necessary to inhibit generation of defects by lowering a film formation rate to an extreme level, a gas barrier property necessary for a flexible electronic device is not obtained at an industrial level requiring high productivity. Although studies are also made to simply increase film thickness of an inorganic film by a vapor phase method or laminate plural layers of an inorganic film, defects tend to continuously grow or more cracks are generated, and thus enhancement of the gas barrier property is not obtained.

Meanwhile, studies are also made to enhance the gas barrier property by alternatively forming plural layers of an inorganic film and an organic film by a vapor phase method to ensure total thickness of an inorganic film without continuously growing defects and also by increasing a gas permeation path length based on different in-plane directional position of defects in each inorganic film, that is, a so-called maze effect. However, in the present state, it cannot be said that the gas barrier property is sufficient, and it is also believed that commercialization is difficult in terms of cost because the processes are complicated and productivity is significantly low compared to performance.

As a method of solving the problems described above, studies are made for enhancing the gas barrier property by modifying a coating layer, which is formed by applying and drying a solution of an inorganic precursor compound, with heat or light. In particular, studies are also made for expressing a high gas barrier property by using polysilazane as an inorganic precursor compound.

Polysilazane is a compound having —(SiR₂—NR)— as a basic structure. When polysilazane is subjected to a heating treatment or a wet heat treatment under an oxidative atmosphere, via silicon oxynitride, it is transformed into silicon oxide. At that time, as direct substitution of nitrogen with oxygen occurs due to oxygen or water vapor present in an atmosphere, it is transformed into silicon nitride in a state with relatively small volume shrinkage, so that it is known that a relatively dense film having few defects in film that are caused by volume shrinkage can be obtained. In treatment of polysilazane, by controlling the oxidizing property of an atmosphere, it is also possible to obtain a relatively dense silicon oxynitride film.

However, forming a dense silicon oxynitride film or silicon oxide film by thermal modification or wet heat modification of polysilazane requires high temperature of not less than 450° C., and thus it is not possible to apply it on a flexible substrate such as plastics.

As a means for solving those problems, a method of forming a silicon oxynitride film or a silicon oxide film by applying vacuum ultraviolet ray irradiation to a coating formed by applying a polysilazane solution has been suggested.

By performing an oxidation reaction using active oxygen or ozone with direct cutting of atomic bonds, which is based only on an action of photons referred to as a photon process, formation of a silicon oxynitride film or a silicon oxide film can be carried out at relatively low temperature by using photo energy of wavelength 100 to 200 nm referred to as vacuum ultraviolet ray (hereinafter, referred to as “VUV” or “VUV ray”) which has higher energy than bonding force between each atom of polysilazane.

In Leibniz Institute of Surface Modification Biannual Report 2008/2009: P18-P21, a method of manufacturing a gas barrier film by irradiating a polysilazane coating with a VUV ray using an excimer lamp is disclosed.

Further, U.S. Patent Application Publication No. 2010/166977 discloses a method of irradiating a polysilazane coating containing a basic catalyst with a VUV ray and an UV ray and manufacturing a gas barrier film. Furthermore, in the examples of the specification of U.S. Patent Application Publication No. 2010/166977, there is an example of a gas barrier film including three laminated gas barrier layers formed on a resin substrate by coating and drying polysilazane and irradiating the polysilazane coating with a VUV ray.

Furthermore, Japanese Patent Application Laid-Open No. 2011-143577 discloses a gas barrier film having a gas barrier layer obtained by providing as an intermediate layer a smoothing layer formed of an organic inorganic composite material on a resin substrate and irradiating a polysilazane coating formed on the smoothing layer with a VUV ray. In the gas barrier film disclosed in Japanese Patent Application Laid-Open No. 2011-143577, by the synergistic effect of enhancement of smoothness of a surface of the substrate and enhancement of adhesiveness with polysilazane through an organic inorganic composite surface, the gas barrier property is significantly enhanced in comparison with the case of providing the polysilazane coating directly on the resin substrate surface.

Furthermore, U.S. Patent Application Publication No. 2010/089636 discloses a technique of adding inorganic nanoparticles to an organic intermediate layer which is disposed between inorganic gas barrier layers formed by vacuum vapor deposition, a sputtering method, or the like, and the organic intermediate layer is called a sealing layer.

According to the structure disclosed in U.S. Patent Application Publication No. 2010/089636, the nanoparticles added to the intermediate layer bury defects of a barrier layer, and entering oxygen or water vapor can be adsorbed. Consequently, the gas barrier property can be enhanced, and in addition inter-layer adhesiveness can be enhanced.

Furthermore, Japanese Patent Application Laid-Open No. 2011-207018 proposes a technique of installing a colloidal silica layer on a gas barrier layer formed by modifying a polysilazane layer coated onto a substrate with an ultraviolet ray having a wavelength of 155 nm to 274 nm. According to this constitution, in a gas barrier film of Japanese Patent Application Laid-Open No. 2011-207018, a high gas barrier property can be obtained.

### SUMMARY OF INVENTION

However, in the technique described in the above literature, it is difficult to sufficiently suppress deterioration of a barrier property under high temperature and high humidity environments, and there is a concern of maintenance for a long period of time of a stable gas barrier property necessary for a flexible electronic device.

Regarding the productivity of the gas barrier film, particularly in the specification of U.S. Patent Application Publication No. 2010/089636, in order to avoid impairment of the gas adsorption effect of inorganic nanoparticles contained in an intermediate layer, that is, gas adsorption nanoparticles, all processes including a process for producing the intermediate layer is required to be performed under vacuum, and there is a problem that it is difficult to enhance the production efficiency.

Accordingly, there has been required a gas barrier film in which an extremely high gas barrier property required for a flexible electronic device and so on and durability capable of maintaining a high gas barrier property under high temperature and high humidity environments can be realized simultaneously and which has good productivity.

The present invention is achieved in view of the problems described above, and an object thereof is to provide a gas barrier film having an extremely excellent gas barrier property and durability, and a gas barrier film having good productivity. Another object of the present invention is to provide a highly durable electronic device using the gas barrier film.

The above objects are achieved by the following constitutions.

Namely, a gas barrier film according to the present invention has a substrate, a first gas barrier layer formed by irradiating a polysilazane-containing layer with a vacuum ultraviolet ray, a second gas barrier layer formed by irradiating a polysilazane-containing layer with a vacuum ultraviolet ray, and a hydrophobic intermediate layer disposed between the first gas barrier layer and the second gas barrier layer and containing a metal compound particle.

Further, an electronic device of the present invention uses the above gas barrier film.

### BRIEF DESCRIPTION OF DRAWINGS

FIG. 1 is a cross-sectional schematic diagram of a gas barrier film according to one embodiment of the present invention.

FIG. 2 is a cross-sectional pattern diagram showing an example of a vacuum ultraviolet ray irradiation device used in the present invention.

FIG. 3 is a cross-sectional schematic diagram of an electronic device according to one embodiment of the present invention.

### DESCRIPTION OF EMBODIMENTS

Hereinafter, embodiments for carrying out the present invention are explained in detail. The range of the invention is not limited to those descriptions. As for embodiments other than the following exemplifications may be suitably practiced in a range not to impair the gist of the invention.

In this specification, “vacuum ultraviolet ray”, “vacuum ultraviolet radiation”, “VUV”, and “VUV ray” specifically mean the light having a wavelength of 100 to 200 nm. “X to Y” indicating a range means that “not less than X and not more than Y”.

Inventor of the present invention conducted intensive studies in view of the problems described above, and as a result, found that, with a gas barrier film having a substrate, a first gas barrier layer formed by irradiating a polysilazane-containing layer with a vacuum ultraviolet ray, a second gas barrier layer formed by irradiating a polysilazane-containing layer with a vacuum ultraviolet ray, and a hydrophobic intermediate layer disposed between the first gas barrier layer and the second gas barrier layer and containing a metal compound particle, a gas barrier film having extremely excellent gas barrier performance and durability can be realized, whereby the inventors reached the invention.

In conventional gas barrier films formed by irradiation of a polysilazane-containing coating, formed on a resin substrate, with a VUV ray, it is difficult to obtain for a long period of time a stable gas barrier property necessary for a flexible electronic device. Regarding this problem, after detailed studies paying attention to the layer configuration and the manufacturing conditions of the gas barrier film, the inventor of the present invention found that an intermediate layer is provided between gas barrier layers, and when the intermediate layer is a layer formed of a specified material, lowering of the gas barrier property can be suppressed even under high temperature and high humidity environments. More specifically, a layer having three-dimensionally continued pores and a hydrophobic property is formed as an intermediate layer between gas barrier layers, whereby a gas barrier film having an excellent gas barrier performance and durability can be obtained.

In order to explain a mechanism of exercise of an advantage according to the constitution of the present invention, the configuration and behavior of a gas barrier film using a general polysilazane coating will be first described.

Since perhydropolysilazane has a Si—H structure, when a layer such as an intermediate layer provided under a polysilazane coating contains an inorganic component, for example, when the layer contains a silica component, a Si—O—Si bond is formed by reaction with Si—OH existing on a substrate surface, and it is considered that the layer is firmly adhered to the polysilazane coating and the intermediate layer in an initial phase.

However, the Si—O—Si bond may be cut into, for example, Si—OH and HO—Si by hydrolysis in a high temperature and high humidity environment. Since water easily enters a gap between temporarily cut Si—OH and HO—Si, the Si—O—Si bonds existing therearound are sequentially cut by hydrolysis.

A film obtained by treating a polysilazane coating with VUV ray, that is, an interface between a gas barrier layer and an intermediate layer are partially peeled based on the above mechanism, and it is considered that deterioration of the gas barrier property progresses.

Meanwhile, as a result of various studies, the inventor of the present invention found that when an intermediate layer is a layer having three-dimensionally continued pores and a hydrophobic property, the intermediate layer can form extremely strong physical bonding estimated as an interpenetration structure with a polysilazane coating. Since the physical bonding is not deteriorated under high temperature and high humidity, it is considered that a gas barrier film having the above constitution can maintain an initial high gas barrier property for a long period of time. When an intermediate layer is thick, there are concerns that transparency of the gas barrier film is lowered, however, when the purpose is to obtain an interpenetration effect, it is not necessary to increase the thickness of the intermediate layer. Accordingly, since the lowering of the transparency is scarcely accompanied, it is possible to obtain a gas barrier film having a high gas barrier property, high transparency, and good durability and productivity.

Meanwhile, since an intermediate layer of the present invention has pores, as described above, when the layer itself has a high hydrophobic property, moisture in the atmosphere is easily condensed in the pores, so that an excessive amount of moisture may be held in the intermediate layer. The moisture reacts with polysilazane when a liquid containing polysilazane is coated onto the intermediate layer, so that hydrolysis of the polysilazane coating excessively progresses, and there is a concern that the gas barrier property is lowered. Accordingly, when a hydrophobic property is imparted to the intermediate layer, the intermediate layer can be prevented from holding moisture. Consequently, the gas barrier film of the invention can maintain a high gas barrier property for a long period of time.

As described above, in the present invention, an intermediate layer having three-dimensionally continued pores and a hydrophobic property is formed, and gas barrier layers are formed above and under the intermediate layer, whereby it is possible to obtain a gas barrier film having a high gas barrier property, high durability and transparency, and good productivity.

The above mechanism is based on a presumption, and the present invention is not limited to the above mechanism at all.

As described above, the present invention can provide a gas barrier film having extremely excellent gas barrier performance and durability and a highly durable electronic device using the gas barrier film.

Hereinafter, details of the constitutional elements of the gas barrier film of the invention will be described.

### <<Gas Barrier Film>>

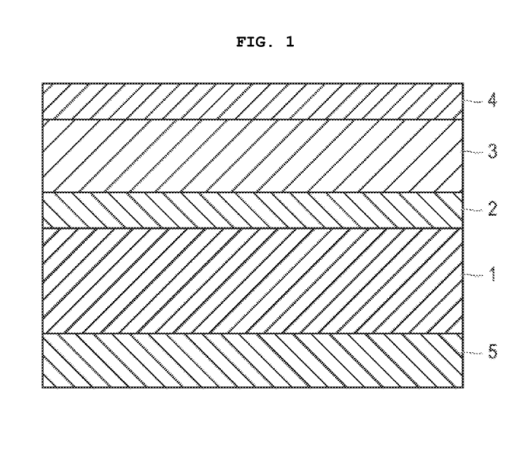

The gas barrier film of the present invention has, as shown in FIG. 1, a substrate 1 as a support, a first gas barrier layer 2 and a second gas barrier layer 4 each formed by irradiating a polysilazane-containing layer with a vacuum ultraviolet ray, and a hydrophobic intermediate layer 3 disposed between the first gas barrier layer 2 and the second gas barrier layer 4 and containing a metal compound particle. Namely, the gas barrier film of the present invention has on the substrate 1 the first gas barrier layer 2, the intermediate layer 3, and the second gas barrier layer 4 in this order.

It is preferable that the first gas barrier layer, the intermediate layer, and the second gas barrier layer are formed by a coating method as described hereinafter. Namely, it is preferable that the polysilazane-containing layer for gas barrier layer formation and the intermediate layer are formed by the coating method. When all the layers are formed by the coating method, a gas barrier film can be manufactured without using a gas phase method, so that productivity is enhanced.

In a gas barrier film having on one surface of a substrate the first gas barrier layer, the intermediate layer, and the second gas barrier layer, the above effect can be obtained, however, the first gas barrier layer, the intermediate layer, and the second gas barrier layer may be formed on both surfaces of the substrate.

[Substrate]

The substrate used in the present invention is a long support which can hold a first gas barrier layer and a second gas barrier layer (simply referred to as “barrier layers”) having a gas barrier property (simply referred to as a “barrier property”) to be described below, and it is formed of the following materials, but not limited thereto.

Examples may include various resin films of polyester such as polyacrylic acid ester, polymethacrylic acid ester, polyethylene terephthalate (PET), polybutylene terephthalate, polyethylene naphthalate (PEN) and polyallylate; polycarbonate (PC); polyvinyl chloride (PVC); polyethylene (PE); polypropylene (PP); polystyrene (PS); nylon (Ny); aromatic polyamide; polyether ether ketone; polysulfone; polyether sulfone; polyimide; polyether imide and so on, a heat resistant transparent film having, as a basic skeleton, silsesquioxane having an organic inorganic hybrid structure (for example, product name Sila-DEC (registered trademark); manufactured by CHISSO Corporation and product name Silplus (registered trademark); manufactured by Nippon Steel & Sumikin Chemical Co., Ltd.), and resin films formed by laminating two or more layers of the foregoing resin.

polyester such as polyethylene terephthalate (PET), polybutylene terephthalate and polyethylene naphthalate (PEN), polycarbonate (PC) and so on are suitably used in terms of costs and ease of acquisition, and the heat resistant transparent film having, as a basic skeleton, silsesquioxane having an organic inorganic hybrid structure can be suitably used in terms of optical transparency, heat resistance, and adhesion with an inorganic layer and a gas barrier layer.

Meanwhile, when the gas barrier film is used for an electronic device application in a flexible display, the processing temperature may be higher than 200° C. during an array manufacturing method. In case of a roll-to-roll manufacture, a certain amount of tension is constantly applied to a substrate. Therefore, when the substrate temperature increases as the substrate is placed under high temperature, elasticity of the substrate dramatically decreases once the substrate temperature becomes higher than glass transition temperature, so that the substrate is elongated due to tension, whereby the gas barrier layer may suffer from damages. Accordingly, it is preferable to use, as a substrate for such applications, a heat resistant material having glass transition temperature being equal to or higher than 150° C. For example, it is preferable to use polyimide, polyether imide, or a heat resistant transparent film having, as a basic skeleton, silsesquioxane having an organic inorganic hybrid structure. However, as the heat resistant resin represented by them is non-crystalline, it has higher water absorbency value and higher dimensional change of a substrate caused by humidity compared to crystalline PET or PEN, so that the gas barrier layer may suffer from damages. However, even when those heat resistant materials are used as a substrate, by virtue of the formation of gas barrier layers on both surfaces, the dimensional change caused by water absorption and desorption in the substrate film itself under severe condition of high temperature and high humidity can be suppressed, and thus damages occurring on the gas barrier layer can be suppressed. Thus, using a heat resistant material having glass transition temperature of not less than 150° C. as a substrate and forming gas barrier layers on both surfaces of the substrate corresponds to one of the preferred embodiments.

The thickness of the substrate is preferably approximately 5.0 to 500 μm, more preferably 25 to 250 μm, and still more preferably 100 to 200 μm.

Further, the substrate is preferably transparent. Herein, “transparency” referred to herein means that light transmission for visible ray (400 to 700 nm) is not less than 80%.

By having a transparent substrate and also a transparent gas barrier layer formed on a substrate, a transparent gas barrier film can be provided, and thus a transparent substrate of an organic EL element can be also produced.

Further, the substrate using the forgoing resin may be either a non-stretched film or a stretched film.

The substrate used in the present invention can be produced by a previously well-known general method. For example, by melting a resin as a material by use of an extruder, and extruding the molten resin through a ring die or a T die to be rapidly cooled, an unstretched substrate, which is substantially amorphous and is not oriented, can be produced.

Further, for the substrate according to the present invention, prior to forming the gas barrier layer, a surface of the substrate may be subjected to corona treatment.

As surface roughness of the substrate used in the present invention, 10-point average roughness Rz defined in JIS B 0601 (2001) is preferably in the range of 1 to 500 nm, more preferably in the range of 5 to 400 nm, and still more preferably in the range of 300 to 350 nm.

On the substrate surface, centerline average roughness Ra defined in JIS B 0601 (2001) is preferably in the range of 0.5 to 12 nm, and more preferably in the range of 1 to 8 nm.

[Anchor Coat Layer]

An anchor coat layer may be further formed between the substrate and the first gas barrier layer according to the present invention. The anchor coat layer is preferably a so-called easily adhesive layer which enhances adhesiveness between the substrate surface and the first gas barrier layer. A commercially available substrate with an easily adhesive layer can be preferably used.

As a material used for the anchor coat layer, a polyester resin, an isocyanate resin, a urethane resin, an acryl resin, an ethylene vinyl alcohol resin, a vinyl-modified resin, an epoxy resin, a modified styrene resin, a modified silicon resin, an alkyl titanate, and the like can be used singly or in combination of two or more thereof.

To these materials for the anchor coat layer can also be added a previously well-known additive. The foregoing anchor coat layer can be formed by applying the materials onto the substrate by a well-known method such as roll coating, gravure coating, knife coating, dip coating, or spray coating, and removing a solvent, a diluent and the like by drying. The coating amount of the foregoing anchor coat layer is preferably about 0.1 to 5.0 g/m² (dry state).

Further, the anchor coat layer may be formed by a vapor phase method such as a physical vapor deposition method or a chemical vapor deposition method. For example, as disclosed in Japanese Patent Application Laid-Open No. 2008-142941, for the purpose of improving adhesiveness or the like, an inorganic film having silicon oxide as a main component can be formed.

Further, although thickness of the anchor coat layer is not limited particularly, the thickness is preferably approximately 0.5 to 10.0 μm.

[Flat and Smooth Layer]

The gas barrier film of the present invention may have further a flat and smooth layer between the substrate and the first gas barrier layer. The flat and smooth layer is provided for flattening the rough surface of a transparent resin film support, on which projections and the like are present, or flattening a transparent inorganic compound layer by filling up unevenness and pinholes generated thereon by projections present on the transparent resin film support. Such a flat and smooth layer is formed basically by curing a photosensitive material or a thermosetting material.

Examples of the photosensitive material used for the flat and smooth layer include a resin composition containing an acrylate compound having a radical-reactive unsaturated compound, a resin composition containing an acrylate compound and a mercapto compound having a thiol group, and a resin composition with a polyfunctional acrylate monomer dissolved therein such as epoxy acrylate, urethane acrylate, polyester acrylate, polyether acrylate, polyethylene glycol acrylate, or glycerol methacrylate. Specifically, a UV curable organic/inorganic hybrid hard coating material OPSTAR (registered trademark) series manufactured by JSR Corporation may be used. Further, any mixture of the resin compositions described above can also be used, and the photosensitive resin is not particularly limited as long as it contains a reactive monomer having at least one photopolymerizable unsaturated bond in a molecule.

Specific examples of the thermosetting material include Tutoprom series manufactured by Clariant (organic polysilazane), SP COAT heat resistant clear painting manufactured by Ceramic Coat Co., Ltd., nanohybrid silicone manufactured by Adeka Corporation, UNIDIC (registered trademark) V-8000 series manufactured by DIC Corporation, EPICLON (registered trademark) EXA-4710 (ultra high heat resistant epoxy resin), various silicone resins manufactured by Shin-Etsu Chemical Co., Ltd., inorganic/organic nanocomposite material SSG coat manufactured by Nitto Boseki Co., Ltd., a thermosetting urethane resin consisting of acryl polyol and isocyanate prepolymer, a phenol resin, a urea melamine resin, an epoxy resin, an unsaturated polyester resin, and a silicone resin, and the like. Among them, a material as an epoxy resin base having heat resistance is particularly preferable.

Although the method of forming the flat and smooth layer is not limited particularly, a wet coating method such as a spray coating method, a blade coating method, or a dipping method, or a dry coating method such as a vapor deposition method is preferable.

In the formation of the flat and smooth layer, additives such as an antioxidant, an ultraviolet ray absorbing agent, and a plasticizer can be added to the foregoing photosensitive resin as necessary. In any flat and smooth layers, regardless of the position at which the flat and smooth layer is laminated, resins and additives suitable for improvement of film formability and prevention of generation of pinholes in the film or the like may be added.

The smoothness of the flat and smooth layer is, in terms of the centerline average roughness Ra defined in JIS B 0601 (2001), preferably 0.5 to 12 nm, and more preferably 1 to 3 nm. Further, on a surface of the flat and smooth layer, the 10-point average roughness Rz defined in JIS B 0601 (2001) is preferably 5 to 50 nm, and more preferably 10 to 40 nm. When the value is less than this range, in the formation of a coating layer to be described later, coatability may be impaired when a coating means is in contact with the surface of the flat and smooth layer by a coating method with a wire bar, a wireless bar or the like. When the value is more than this range, smoothing is insufficient against the surface roughness of the substrate, there is no point in providing the flat and smooth layer.

Thickness of the flat and smooth layer is preferably in the range of 1 to 10 μm, and more preferably in the range of 2 to 7 μm.

The flat and smooth layer may be formed between the substrate and the first gas barrier layer, along with the anchor coat layer.

[Bleed Out Preventing Layer]

As shown in FIG. 1, the substrate of the gas barrier film of the present invention may have a bleed out preventing layer 5 on a surface opposite to a surface on which the first gas barrier layer 2 and the second gas barrier layer 4 are provided.

The bleed out preventing layer is provided for the purpose of suppressing such a phenomenon that unreacted oligomers and so on are transferred from the interior to the surface of the film substrate to contaminate the contact surface when the film is heated. The bleed out preventing layer may have essentially the same structure as that of the flat and smooth layer as long as it has the function described above.

The bleed out preventing layer is formed using a material and a method similar to those described in paragraphs to [0119] of Japanese Patent Application Laid-Open No. 2012-228859, for example.

[Gas Barrier Layer]

The first gas barrier layer and the second gas barrier layer according to the present invention are formed by irradiating a polysilazane-containing layer with a vacuum ultraviolet ray. Although the forming conditions of the first gas barrier layer and the second gas barrier layer (such as modifying treatment conditions including the kind of polysilazane to be used, thickness of a coating, and a vacuum ultraviolet ray irradiation condition) may be different from each other, when the first gas barrier layer and the second gas barrier layer are formed under the same condition, the manufacturing process is not made complicated, and thus it is preferable.

Hereinafter, the first gas barrier layer and the second gas barrier layer are referred simply to as “gas barrier layers”, and their features will be explained.

(Polysilazane)

“Polysilazane” according to the present invention is a polymer having a silicon-nitrogen bond in the structure and is a polymer as a precursor of silicon oxynitride, and polysilazane having the following structure is preferably used.

—Si(R₁)(R₂)—N(R₃)—

In the formula, R₁, R₂ and R₃ each represent a hydrogen atom, an alkyl group, an alkenyl group, a cycloalkyl group, an aryl group, an alkylsilyl group, an alkylamino group, or an alkoxy group.

In the present invention, from the viewpoint of film density of the obtained gas barrier layer, perhydropolysilazane in which all of R₁, R₂ and R₃ are a hydrogen atom is particularly preferable.

Perhydropolysilazane is presumed to have a structure containing a straight chain and a ring structure mainly composed of a 6- and 8-membered ring, and its molecular weight is about 600 to 2,000 (polystyrene conversion value based on gel permeation chromatography) in terms of a number average molecular weight (Mn). It is a material of liquid or solid.

Polysilazane is commercially available in a solution state in which polysilazane is dissolved in an organic solvent, and the commercially available product itself can be used as a coating liquid containing polysilazane. Examples of a commercially available polysilazane solution include NN120-20, NAX120-20 and NL120-20, that are manufactured by AZ Electronic Materials.

The first gas barrier layer can be formed by coating a polysilazane-containing coating liquid onto the substrate, drying the coating liquid, and then irradiating the coating with a vacuum ultraviolet ray. Thereafter, after formation of the intermediate layer to be described in detail later, the polysilazane-containing coating liquid is further coated onto the intermediate layer, dried, and irradiated with a vacuum ultraviolet ray, whereby the second gas barrier layer can be formed.

As an organic solvent to prepare the polysilazane-containing coating liquid, it is preferable to avoid using an alcoholic solvent or those containing moisture which easily react with polysilazane.

Examples of the organic solvent include a hydrocarbon solvent such as an aliphatic hydrocarbon, an alicyclic hydrocarbon or an aromatic hydrocarbon; a halogenated hydrocarbon solvent; an ether such as an aliphatic ether, or an alicyclic ether. In particular, usable solvents include: hydrocarbons such as pentane, hexane, cyclohexane, toluene, xylene, SOLVESSO, and TARBEN; halogenated hydrocarbons such as methylene chloride, or trichloroethane; and ethers such as dibutyl ether, dioxane, or tetrahydrofuran.

Those organic solvents may be chosen in accordance with the purpose, such as solubility of polysilazane, and an evaporation rate of an organic solvent, and plural organic solvents may be mixed.

Although the polysilazane concentration in the polysilazane-containing coating liquid varies in accordance with the film thickness of the gas barrier layer or the pot life of the coating liquid, it is preferable to be approximately 0.2 to 35% by mass.

In order to promote the modification into a silicon oxynitride compound, an amine catalyst or a metal catalyst, including a Pt compound such as Pt acetyl acetonate, a Pd compound such as Pd propionate, and a Rh compound such as Rh acetylacetonate, may be added to the coating liquid. In the present invention, the amine catalyst is particularly preferably used.

Specific examples of the amine catalyst include N,N-diethylethanolamine, N,N-dimethylethanolamine, triethanolamine, triethylamine, 3-morpholino propylamine, N,N,N′,N′-tetramethyl-1,3-diaminopropane, and N,N,N′,N′-tetramethyl-1,6-diaminohexanoic acid.

The amount of addition of those catalysts to polysilazane is preferably in the range of 0.1 to 10% by mass relative to the whole amount of the coating liquid, more preferably in the range of 0.2 to 5% by mass, and still more preferably in the range of 0.5 to 2% by mass. By having the amount of addition of the catalyst within the range, having an excessive formation amount of silanol, a decrease in film density, and an increase in film defects that are caused by a rapid progress of the reaction can be avoided.

As for the method of applying the polysilazane-containing coating liquid onto a substrate, any suitable method may be used.

Specific examples thereof include a roll coating method, a flow coating method, an inkjet method, a spray coating method, a printing method, a dip coating method, a cast film forming method, and a gravure printing method.

The thickness of a coating can be suitably set according to purposes. For example, the thickness of the coating as thickness after drying is preferably in the range of 1 nm to 2 μm, more preferably in the range of 10 nm to 1.5 μm, more preferably in the range of 50 nm to 1 μm, still more preferably in the range of 70 nm to 500 nm, and particularly preferably in the range of 100 nm to 300 nm. When the thickness of the coating is not less than 1 nm, a good gas barrier performance can be exhibited. When the thickness of the coating is not more than 2 μm, a dense silicon oxynitride film can be effectively prevented from being cracked. As an example of a method of simultaneously realizing both the enhancement of the gas barrier performance and the prevention of crack, the total film thickness is kept constant, and a layer may be subdivided. According to this constitution, residual stress in the formation of the silicon oxynitride film can be reduced.

In the gas barrier layer according to the present invention, in the process of irradiating the layer containing polysilazane with a vacuum ultraviolet ray, at least a portion of polysilazane is modified to silicon oxynitride.

Herein, a presumed mechanism for having modification of a layer containing polysilazane by a vacuum ultraviolet ray irradiation process to obtain a specific composition of SiOₓN_{y} will be explained in view of perhydropolysilazane as an example.

Perhydropolysilazane can be expressed by the composition of “—(SiH₂—NH)ₓ-”. When it is expressed by SiOₓN_{y}, x=0 and y=1. To have x>0, an external oxygen source is necessary. In this regard, oxygen or moisture contained in polysilazane coating liquid, oxygen or moisture incorporated into a coating from an atmosphere during a coating and drying process, oxygen, moisture, ozone, or singlet oxygen incorporated into a coating from an atmosphere during a vacuum ultraviolet ray irradiation process, oxygen or moisture migrating as an out gas from a substrate side into a coating caused by heat or the like applied during a vacuum ultraviolet ray irradiation process, or when the vacuum ultraviolet ray irradiation process is performed in a non-oxidative atmosphere, oxygen or moisture incorporated into a coating from an atmosphere when a shift is made from a non-oxidative atmosphere to an oxidative atmosphere, becomes an oxygen source.

Meanwhile, regarding y, since the condition for Si to undergo nitridation than oxidation is believed to be highly extraordinary, an upper limit of y is basically 1.

Further, in view of the relation among bonding arms of Si, O, and N, x and y are basically in the range of 2×+3y≦4. In a state where y=0, that is, fully progressed oxidation state, a silanol group is contained in the coating, and there may be a case in which x is in the range of 2<x<2.5.

A reaction mechanism presumed to be involved with an occurrence of silicon oxynitride and further silicon oxide from perhydropolysilazane by the vacuum ultraviolet ray irradiation process will be described hereinafter.

(1) Dehydrogenation and Formation of Si—N Bond Accompanied Therewith

It is believed that Si—H bond or N—H bond in perhydropolysilazane is relatively easily broken by excitation or the like by vacuum ultraviolet ray irradiation and binds again as Si—N under an inert atmosphere (non-bonding arm of Si may be also formed). That is, it is cured as SiN_{y} composition without oxidation. In this case, thus breakage of a polymer main chain does not occur. Breakage of Si—H bond or N—H bond is promoted by presence of a catalyst or by heating. Broken H is released as H₂ to an outside of the film.

(2) Formation of Si—O—Si Bond by Hydrolysis and Dehydration Condensation

According to hydrolysis of Si—N bond in perhydropolysilazane by water and breakage of a polymer main chain, Si—OH is formed. According to dehydration condensation of two Si—OH, curing is obtained with formation of Si—O—Si bond. Although the reaction occurs also in air, it is believed that, during vacuum ultraviolet ray irradiation under an inert atmosphere, water vapor generated as an out gas from a substrate caused by heat of irradiation is believed to a main source of moisture. When moisture is present in an excessive amount, Si—OH not consumed by dehydration condensation remains, and thus a curing film with low gas barrier property that is represented by the composition of SiO_{2.1} to SiO_{2.3} is yielded.

(3) Direct Oxygenation and Formation of Si—O—Si Bond Caused by Singlet Oxygen

When a suitable amount of oxygen is present in an atmosphere during vacuum ultraviolet ray irradiation, singlet oxygen having greatly high oxidizing ability is formed. H and N in perhydropolysilazane are replaced with O to form a Si—O—Si bond, and thus causing curing. It is also considered that recombination of bonds may also occur according to breakage of a polymer main chain.

(4) Oxidation Accompanied with Si—N Bond Breakage Caused by Vacuum Ultraviolet Ray Irradiation and Excitation

It is believed that, since energy of vacuum ultraviolet ray is greater than the bond energy of Si—N in perhydropolysilazane, Si—N bond is broken and oxidized to generate Si—O—Si bond or Si—O—N bond when an oxygen source such as oxygen, ozone, or water is present in the neighborhood. It is believed that recombination of bonds may also occur according to breakage of a polymer main chain.

Adjusting the composition of silicon oxynitride in a layer which is obtained by performing vacuum ultraviolet ray irradiation on a layer containing polysilazane can be carried out by controlling an oxidation state by combining suitably the oxidation mechanisms (1) to (4) described above.

For the vacuum ultraviolet ray irradiation process in the present invention, an illuminance of the vacuum ultraviolet ray on the coating, which is applied to the coating of the polysilazane layer, is preferably 1 mW/cm² to 10 W/cm², more preferably 30 mW/cm² to 200 mW/cm², and still more preferably 50 mW/cm² to 160 mW/cm². When the illuminance of the vacuum ultraviolet ray is less than 1 mW/cm², there is a concern that modification efficiency is significantly lowered, and when the illuminance of the vacuum ultraviolet ray is more than 10 W/cm², there are concerns that ablation occurs in a coating, or the substrate is damaged.

Energy amount of the vacuum ultraviolet ray irradiation on the coating surface of the polysilazane layer is preferably 10 to 10,000 mJ/cm², more preferably 100 to 8,000 mJ/cm², still more preferably 200 to 6,000 mJ/cm², and particularly preferably 500 to 5,000 mJ/cm². When the irradiation energy amount is less than 10 mJ/cm², there is a concern that modification is insufficient, and when the irradiation energy amount is more than 10,000 mJ/cm², there is a concern that crack occurs due to excessive modification, or the substrate is thermally deformed.

As for a light source of vacuum ultraviolet ray, a rare gas excimer lamp is preferably used. As such a rare gas excimer lamp, the rare gas excimer lamp described in paragraphs [0058] to [0071] of Japanese Patent Application Laid-Open No. 2012-228859 may be used, for example.

Among the rare gas excimer lamps, an Xe excimer lamp radiates ultraviolet ray with single wavelength, that is, a short wavelength of 172 nm, and thus the radiation efficiency is excellent. As oxygen has a high absorption coefficient of the above-mentioned light, radical oxygen atom species or ozone can be generated even with a tiny amount of oxygen.

Further, energy of the light having a short wavelength of 172 nm is known to have a high ability of dissociating bonds in an organic substance. Due to high energy of active oxygen or ozone and ultraviolet radiation, the modification of polysilazane layer can be achieved within a short time.

Thus, compared to a cleaning by a low pressure mercury lamp having emission from a wavelength of 185 nm, 254 nm or by plasma, it enables shortening of time for the processing accompanied with high through-put or decreasing an area for facilities, and irradiation onto an organic material, a plastic substrate, or the like that are prone to suffer from damages caused by heat.

As the excimer lamp has high efficiency of light generation, it is possible to have lighting with an input of low electric power. Further, light with long wavelength, which can be a cause of temperature increase by light, is not generated, and energy is irradiated in an ultraviolet region, that is, with a short wavelength, and thus it has a characteristic that surface temperature increase in the subject for degradation is suppressed. For such reasons, it is suitable for a flexible film material like PET which is believed to be easily affected by heat.

Oxygen is required for the reaction in the ultraviolet ray irradiation, however, as vacuum ultraviolet ray has absorption by oxygen, efficiency may be easily lowered during the ultraviolet ray irradiation process. Thus, vacuum ultraviolet ray irradiation is preferably carried out in a state in which oxygen concentration is as low as possible. Namely, oxygen concentration during vacuum ultraviolet ray irradiation is preferably 10 to 10,000 ppm, more preferably 50 to 5,000 ppm, and still more preferably 1,000 to 4,500 ppm.

Dry inert gas is preferred as a gas filling the irradiation atmosphere used in the vacuum ultraviolet ray irradiation. In particular, dry nitrogen gas is preferred from the viewpoint of cost. Adjustment of oxygen concentration can be achieved by changing flow amount ratio after measuring flow amount of oxygen gas and inert gas that are introduced into an irradiation tank.

Heating a coating simultaneously with the vacuum ultraviolet ray irradiation is also preferably conducted to promote the reaction (also referred to as an oxidizing reaction, a conversion treatment, or a modifying treatment). Examples of a heating method include a method of bringing the substrate into contact with a heating element such as a heat block and thereby heating the coating through thermal conduction, a method of heating an environment in which the coating is placed by an external heater using resistance wires and so on, and a method of using light of an infrared region such as an IR heater, however, the heating method is not limited to these methods. When heating treatment is performed, a method in which flatness of the coating can be maintained may be suitably selected.

The temperature at which the coating is heated is preferably in the range of 40° C. to 250° C., and more preferably in the range of 60° C. to 150° C. The heating duration is preferably in the range of 0.1 minute to 1,000 minutes.

In the gas barrier layer according to the invention, three or more gas barrier layers are laminated to form a multilayer structure, and an intermediate layer to be hereinafter described may be formed between each gas barrier layers.

[Intermediate Layer]

In the present invention, the intermediate layer having hydrophobicity is disposed between the gas barrier layers, that is, between the first gas barrier layer and the second gas barrier layer. More specifically, the intermediate layer is formed so that while one surface is in contact with the first gas barrier layer, the other surface is in contact with the second gas barrier layer.

Furthermore, the intermediate layer of the present invention contains a metal compound particle (A). Further, the intermediate layer may contain a hydrophobic material or other additives (such as a surfactant or a pH adjuster) if necessary.

(Configuration of Intermediate Layer)

As the form of the metal compound particle (A) contained in the intermediate layer, there are following forms:
(i) the form in which the intermediate layer contains only a hydrophilic metal compound particle (A-1);
(ii) the form in which the intermediate layer contains only a hydrophobic metal compound particle (A-2); and
(iii) the form in which the intermediate layer contains both a hydrophilic metal compound particle (A-1) and a hydrophobic metal compound particle (A-2).

In the form (i), the intermediate layer according to the present invention contains a hydrophobic material (B). In the forms (ii) and (iii), the intermediate layer according to the invention may or may not contain the hydrophobic material (B).

Accordingly, the intermediate layer has the following configuration.

In the case of (i)

(i-1) the intermediate layer contains a hydrophilic metal compound particle and a hydrophobic material ((A-1)+(B)).

In the case of (ii)

(ii-1) the intermediate layer contains a hydrophobic metal compound particle and does not contain a hydrophobic material (only (A-2)), and

(ii-2) the intermediate layer contains a hydrophobic metal compound particle and a hydrophobic material ((A-2)+(B)).

In the case of (iii)

(iii-1) the intermediate layer contains a hydrophilic metal compound particle and a hydrophobic metal compound particle and does not contain a hydrophobic material ((A-1)+(A-2)), and

(iii-2) the intermediate layer contains a hydrophilic metal compound particle, a hydrophobic metal compound particle, and a hydrophobic material ((A-1)+(A-2)+(B)).

Among the (i) to (iii), the form (ii) is preferable from such a viewpoint that the hydrophobicity of the intermediate layer is enhanced to maintain the gas barrier property for a long period of time, and (ii-1) is particularly preferable.

In the case (i), the fact that the intermediate layer is “hydrophobic” means that the intermediate layer contains not less than 0.1% by mass of the hydrophobic material (B) relative to 100% by mass of a total amount of the hydrophilic metal compound particle (A-1) and the hydrophobic material (B).

In the case of (ii), since the intermediate layer inevitably contains the hydrophobic metal compound particle (A-2), the intermediate layer is hydrophobic.

In the case of (iii), the fact that the intermediate layer is “hydrophobic” means the following matter. Namely, in the form (iii-1), when not less than 0.1% by mass of the hydrophobic metal compound particle is contained, relative to 100% by mass of a total amount of the hydrophilic metal compound particle and the hydrophobic metal compound particle, the intermediate layer is “hydrophobic”. In the form (iii-2), when the total amount of the hydrophobic metal compound particle and the hydrophobic material is not less than 0.1% by mass, relative to 100% by mass of a total amount of the hydrophilic metal compound particle, the hydrophobic metal compound particle, and the hydrophobic material, the intermediate layer is “hydrophobic”.

The intermediate layer may further contain other additives such as a commonly known surfactant and a pH adjuster. The amount of those additives added is preferably in the range of 0.01 to 1% by mass with respect to 100% by mass of total amount of the metal compound particle and the hydrophobic material.

In the metal compound particle (A) according to the present invention, the particle diameter is preferably in the range of 1 to 200 nm. In this specification, when the metal compound particle (A) has a spherical shape, the particle diameter means a diameter of the metal compound particle (A), and when the metal compound particle (A) does not have a spherical shape, the particle diameter means a long diameter of the metal compound particle (A). The particle diameter of the metal compound particle (A) is measured by high magnification SEM observation, and more specifically, an average value obtained by measuring 100 particles via SEM observation is adopted.

When the particle diameter of the metal compound particle (A) is not less than 1 nm, three-dimensionally continued pores can be formed in the intermediate layer, and the intermediate layer and the gas barrier layer easily have an interpenetration structure; therefore, the gas barrier layer is less likely to be peeled from the substrate. When the particle diameter is not more than 200 nm, excessive irregularities are not formed on a surface of the intermediate layer, and it is possible to suppress deterioration of the gas barrier property of the gas barrier layer due to irregularities.

When the particle diameter is in the range of 5 to 150 nm, it is more preferable because a balance between enlargement of a diameter of the pore and smoothness of the intermediate layer surface is improved. When the particle diameter is in the range of 10 to 130 nm, it is still more preferable because the balance between the pore diameter and the smoothness is further improved.

Furthermore, it is preferable that the hydrophobic intermediate layer contains 65 to 100% by mass of the metal compound particle (A) having a particle diameter of 1 to 200 nm and 0 to 35% by mass of the hydrophobic material (B), relative to 100% by mass of a total amount of the metal compound particle (A) and the hydrophobic material (B).

It is preferable that the content of the metal compound particle (A) in the intermediate layer is not less than 65% by mass with respect to the total amount of the metal compound particle (A) and the hydrophobic material (B). In general, when spheres having constant diameters are randomly filled, a volume filling rate thereof is about 60%, and porosity is about 40%. Accordingly, when a layer is formed by coating a liquid containing spherical particles mixed with a liquid binder, if the particles and the binder have the same specific gravity, no void is formed. Since an actual coating layer is variously affected, it is not simple as described above. Thus, as a result of intensive studies made by the present inventor, the present inventors found that the pores were formed on the intermediate layer surface when the content of the metal compound particle in the intermediate layer was not less than 65% by mass, and a preferred embodiment was provided. The shape, size, and so on of the pore on the intermediate layer surface can be confirmed by, for example, measuring a surface shape with the use of AFM.

The content of the metal compound particle (A) is more preferably not less than 70% by mass, and still more preferably not less than 80% by mass in terms of the fact that the porosity of the intermediate layer can be further increased.

It is preferable that the metal compound particle is not substantially dissolved in a solvent of the polysilazane-containing coating liquid. Namely, it is preferable that the metal compound particle is not substantially dissolved in a solvent used when the gas barrier layer is formed. Further, it is preferable that even when the metal compound particles are singly used, a film is formed in the state in which the particle contacting portions are bonded when the metal compound particles are coated and dried.

Preferable ranges of the contents of respective constituent components in the above cases of (i-1) to (iii-2) are as follows.

In the case of (i-1) ((A-1)+(B))

In the case where the hydrophilic metal compound particle (A-1) and the hydrophobic material (B) are used, a content of the hydrophilic metal compound particle (A-1) is preferably 65 to 99.9% by mass, relative to 100% by mass of a total amount of the metal compound particle (A-1) and the hydrophobic material (B), more preferably 70 to 99.5% by mass, and still more preferably 80 to 99% by mass.

A content of the hydrophobic material (B) is preferably 0.1 to 35% by mass, relative to 100% by mass of the total amount of the metal compound particle (A-1) and the hydrophobic material (B), more preferably 0.5 to 30% by mass, and still more preferably 5 to 30% by mass. When the content is within the range, sufficient hydrophobicity is imparted to the intermediate layer, and agglomeration of moisture into the pore can be suppressed.

In the case of (ii-1) or (ii-2) (only (A-2) or (A-2)+(B))

In the case where the intermediate layer contains only the hydrophobic metal compound particle (A-2) as the metal compound particle (A), the hydrophobic material may be or may not be used. This is because even if the hydrophobic material is not used, the hydrophobicity can be imparted to the intermediate layer. Accordingly, In the case where the intermediate layer contains the hydrophobic material (B), a content of the hydrophobic metal compound particle (A-2) is preferably in the range of 65 to 100% by mass, relative to 100% by mass of a total amount of the metal compound particle (A-2) and the hydrophobic material (B). From such a viewpoint that the porosity of the intermediate layer can be further increased, the content is preferably 70 to 100% by mass, and more preferably 80 to 100% by mass.

A content of the hydrophobic material (B) is preferably 0 to 35% by mass, relative to 100% by mass of a total amount of the metal compound particle (A-1) and the hydrophobic material (B), more preferably 0.5 to 30% by mass, and still more preferably 5 to 20% by mass.

When the content is within the above ranges, sufficient hydrophobicity is imparted to the intermediate layer, and the agglomeration of moisture into the pore can be suppressed.

In the case of (iii-1) ((A-1)+(A-2))

In the case where the hydrophilic metal compound particle (A-1) and the hydrophobic metal compound particle (A-2) are used together, and the hydrophobic material (B) is not used, a content of the hydrophilic metal compound particle (A-1) is preferably 65 to 99.9% by mass, relative to 100% by mass of a total of the metal compound particle, more preferably 70 to 99.5% by mass, and still more preferably 80 to 99% by mass.

A content of the hydrophobic metal compound particle (A-2) is preferably 0.1 to 35% by mass, relative to 100% by mass of a total of the metal compound particle, more preferably 0.5 to 30% by mass, and still more preferably 1 to 20% by mass.

When the content is within the above ranges, sufficient hydrophobicity is imparted to the intermediate layer, and the agglomeration of moisture into the pore can be suppressed.

In the case of (iii-2) ((A-1)+(A-2)+(B))

In the case where both the hydrophilic metal compound particle (A-1) and the hydrophobic metal compound particle (A-2) are contained as the metal compound particle (A), and, in addition, the hydrophobic material (B) is contained, a content of the hydrophilic metal compound particle (A-1) is preferably 65 to 99.9% by mass, relative to 100% by mass of a total of the total amount of the hydrophilic metal compound particle and the hydrophobic metal compound particle and the hydrophobic material (B), more preferably 70 to 99.5% by mass, and still more preferably 80 to 99% by mass.

A content of the hydrophobic material (B) is preferably 0.1 to 35% by mass, relative to 100% by mass of a total amount of a total amount of the hydrophilic metal compound particle and the hydrophobic metal compound particle, and the hydrophobic material (B), more preferably 0.5 to 30% by mass, and still more preferably 1 to 20% by mass.

When the content is within the above ranges, sufficient hydrophobicity is imparted to the intermediate layer, and the agglomeration of moisture into the pore can be suppressed.

As described above, various constitutions can be adopted based on the assumption that the intermediate layer contains the metal compound particle (A) and has hydrophobicity, however, in particular, the following forms are preferred: (I) the metal compound particle (A) is a colloidal silica particle, and a content of the colloidal silica particle is 65 to 99.9% by mass relative to 100% by mass of a total of the colloidal silica particle and the hydrophobic material (B); or (II) the metal compound particle (A) is a polyorganosiloxane particle or a polyorganosilsesquioxane particle, and a content of the polyorganosiloxane particle or the polyorganosilsesquioxane particle is 65 to 100% by mass relative to 100% by mass of a total content of the polyorganosiloxane particle or the polyorganosilsesquioxane particle and the hydrophobic material (B). When any one of the configurations (I) and (II) is adopted, the intermediate layer is easily formed by a coating method, and, at the same time, a highly durable gas barrier film can be obtained.

Hereinafter, the metal compound particle and the hydrophobic material will be described in detail.

(Hydrophilic Metal Compound Particle)

Although specific examples of the hydrophilic metal compound particle include the following hydrophilic metal compound particles, the hydrophilic metal compound particle is not limited thereto. “Hydrophilic” materials or particles mean those that are more easily dissolved in water than “hydrophobic” materials or particles to be described below.

Examples of the hydrophilic metal compound particle include metal oxide nanoparticle colloid such as colloidal silica particles, alumina sol particles, and titania sol particles. Among those, the colloidal silica particles are particularly preferred. This is because colloidal silica has advantages that the film-forming property is high even under a relatively low temperature drying condition.

As colloidal silica, any of a water dispersed product and a solvent (such as alcohol) dispersed product may be used. Those products are available as commercial products from, for example, Nissan Chemical Industries, Ltd.

As specific commercially available colloidal silica products manufactured by Nissan Chemical Industries, Ltd., the following products can be preferably used.

Examples of water-dispersible alkaline colloidal silica stabilized with Na include Snowtex (registered trademark) 30 (particle diameter: 10 to 20 nm), Snowtex (registered trademark) S (particle diameter: 8 to 11 nm), Snowtex (registered trademark) XS (particle diameter: 4 to 6 nm), Snowtex (registered trademark) 20L (particle diameter: 40 to 50 nm), Snowtex (registered trademark) XL (particle diameter: 50 to 60 nm), and Snowtex (registered trademark) ZL (particle diameter: 70 to 100 nm).

Examples of water-dispersible alkaline colloidal silica stabilized with ammonia include Snowtex (registered trademark) N (particle diameter: 10 to 20 nm), Snowtex (registered trademark) NS (particle diameter: 8 to 11 nm), and Snowtex (registered trademark) NXS (particle diameter: 4 to 6 nm).

Examples of acidic type of water-dispersible colloidal silica from which Na is removed include Snowtex (registered trademark) 0 (particle diameter: 10 to 20 nm), Snowtex (registered trademark) OS (particle diameter: 8 to 11 nm), and Snowtex (registered trademark) OXS (particle diameter: 4 to 6 nm).

An example of a special processing type of water-dispersible colloidal silica stable in a neutral region includes Snowtex (registered trademark) C (particle diameter: 10 to 20 nm).

Examples of solvent-dispersable colloidal silica include methanol silica sol (methanol dispersion, particle diameter: 10 to 20 nm), IPA-ST (isopropanol dispersion, particle diameter: 10 to 20 nm), and IPA-ST-ZL (isopropanol dispersion, particle diameter: 70 to 100 nm).

In the present invention, as the shape of colloidal silica, a chain-like or beaded (pearl necklace-like) colloidal silica formed by, for example, connecting substantially spherical shaped particles can be preferably used. By virtue of the use of the chain-like or beaded colloidal silica, the film-forming property of the intermediate layer is enhanced, and, at the same time, the porosity is increased, so that adhesiveness between the intermediate layer and the gas barrier layer is further enhanced.

Chain-like or beaded colloidal silica particles are also available as a commercial product from, for example, Nissan Chemical Industries, Ltd. Specifically, the following products can be preferably used.

Examples of chain-like colloidal silica include Snowtex (registered trademark) UP (particle diameter: 40 to 100 nm) of water-dispersible alkaline colloidal silica stabilized with Na, Snowtex (registered trademark) OUP (particle diameter: 40 to 100 nm) of acidic type of water-dispersible colloidal silica from which Na is removed, and IPA-ST-UP (isopropanol dispersion, particle diameter: 40 to 100 nm) of solvent-dispersible colloidal silica.

Examples of beaded colloidal silica include Snowtex (registered trademark) PS-S (particle diameter: 80 to 120 nm) of water-dispersible alkaline colloidal silica stabilized with Na and Snowtex (registered trademark) PS-M (particle diameter: 80 to 120 nm).

Hereinabove, the exemplified hydrophilic metal compound particles may be used singly, or if mixing is allowed, a mixture of plural kinds of them may be suitably used.

(Hydrophobic Material)

When the intermediate layer contains only the hydrophilic metal compound particle as the metal compound particle (A), the intermediate layer contains the hydrophobic material.

The hydrophobic material means a material which is not substantially dissolved in water among organic materials. Specifically, the hydrophobic material is a material whose amount dissolved in water of 20° C./100 g is less than 0.1 g.

Specific examples of the hydrophobic material include wax and resin.

Specific examples of wax include paraffin, polyolefin, polyethylene wax, microcrystalline wax, fatty acid-based wax, and silicone oil. The molecular weights of those waxes are preferably approximately 800 to 10,000. When a solvent of a coating liquid for the intermediate layer is an aqueous solvent, in order to facilitate emulsifying in the coating liquid, those waxes are oxidized, a polar group such as hydroxyl group, ester group, carboxyl group, aldehyde group, or peroxide group can be introduced. Further, in order to lower the softening point, for example, those waxes may be mixed with stearoamide, linolenamide, laurylamide, myristelamide, hardened beef fatty acid amide, palmitoamide, oleic amide, rice fatty acid amide, coconut fatty acid amide, or methylol-modified compounds of these fatty acid amides, methylenebisstearoamide, or ethylenebisstearoamide. There are also usable coumarone-indene resin, rosin-modified phenol resin, terpene-modified phenol resin, xylene resin, ketone resin, acryl resin, ionomer and the foregoing resin copolymer.

Specific examples of resin include polystyrene, polypropylene, polybutadiene, polyisoprene, diene (co)polymers such as ethylene-butadiene copolymer, synthetic rubbers such as styrene-butadiene copolymer, methyl methacrylate-butadiene copolymer, acrylonitrile-butadiene copolymer, (meth)acrylic (co)polymers such as polymethylmethacrylate, methyl methacrylate-(2-ethyl hexyl acrylate) copolymer, methyl methacrylate-methacrylic acid copolymer, methyl acrylate-(N-methylolacrylamide) copolymer and polyacrylonitrile, vinyl ester (co)polymers such as polyvinyl acetate, vinyl acetate-vinyl propionate copolymer and vinyl acetate-ethylene copolymer, vinyl acetate-(2-ethyl hexyl acrylate) copolymer, polyvinyl chloride, polyvinylidene chloride, polystyrene, and copolymers of them. Among them, polystyrene, (meth)acrylic (co)polymer, vinylester (co)polymer, and synthetic rubbers are preferably used.

The hydrophobic material may be used singly, or two or more kinds of the hydrophobic materials may be used in combination. As the hydrophobic materials, synthetics or commercial products may be used.

(Hydrophobic Metal Compound Particle)

The hydrophobic metal compound particles used in the present invention mean particles stably dispersed in a nonaqueous organic solvent and not substantially dispersed in water. The fact that “stably dispersed in a nonaqueous organic solvent” specifically means that when the hydrophobic metal compound particles are dispersed in any one of nonaqueous organic solvents selected from methyl ethyl ketone, methyl isobutyl ketone, and toluene, the dispersion state is kept without substantially causing sedimentation or agglomeration even after still standing at 20° C. for 24 hours. The fact that “particles not substantially dispersed in water” means that water is added to a nonaqueous organic solvent in which the hydrophobic metal compound particles are dispersed (at this time, the volume ratio between the organic solvent and water is 50/50) then satisfactorily stirred and mixed at 500 rpm for 10 minutes, and thereafter left to stand in a stationary state, and when the nonaqueous organic solvent and water are separated, the hydrophobic metal compound particles are not substantially transferred to a water phase.

Examples of the hydrophobic metal compound particle include the particle formed by covering the foregoing hydrophilic metal compound particle with the hydrophobic material. The hydrophobic metal compound particle in this form can be obtained by, for example, a method of applying surface modification to silica sol with a silane coupling agent in the presence of an amphiphilic organic solvent and obtaining hydrophobic silica sol, described in Japanese Patent Application Laid-Open No. 2005-314197, or a method of modifying surfaces of nanoparticles, formed of metal oxide, metalloid oxide, metal hydroxide, or metalloid hydroxide with polysiloxane and thereby obtaining the nanoparticles stably dispersed to a solvent, described in Japanese Patent Application Laid-Open No. 2006-290725.

As the hydrophobic metal compound particle, polyorganosiloxane particles or polyorganosilsesquioxane particles can be preferably used. In particular, a polyorganosiloxane or polyorganosilsesquioxane compound having an organic group and a reactive group can be preferably used. Examples of the reactive group include Si—H, Si—OH, and Si—OR, and Si—H and Si—OH are more preferable.

Specific examples of the polyorganosiloxane particle include polyorganosiloxane having a Si—H terminal and represented by the following formula (1), polyorganosiloxane having a Si—OH terminal and represented by the following formula (2), and polyorganosiloxane having Si—H in the side chain and represented by the following formula (3):

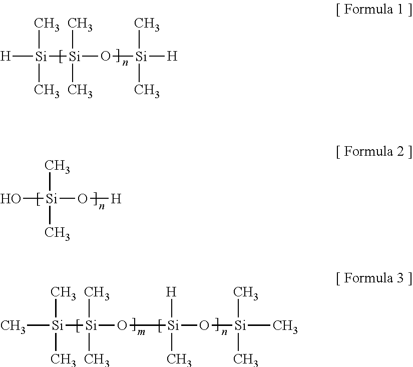

n in the formulae (1) and (2) are each independently in the range of 1 to 100.

In the formula (3), m is in the range of 0 to 99, and n is in the range of 1 to 100. n is preferably 30 to 100, and more preferably 50 to 100.

In the formulae (1) to (3), although an organic group is methyl, the organic group may be, for example, a phenyl group, or the respective organic groups may be different from each other.

Further specific examples of polyorganosiloxane include the compounds represented by the following S1 to S16; however, polyorganosiloxane is not limited thereto.

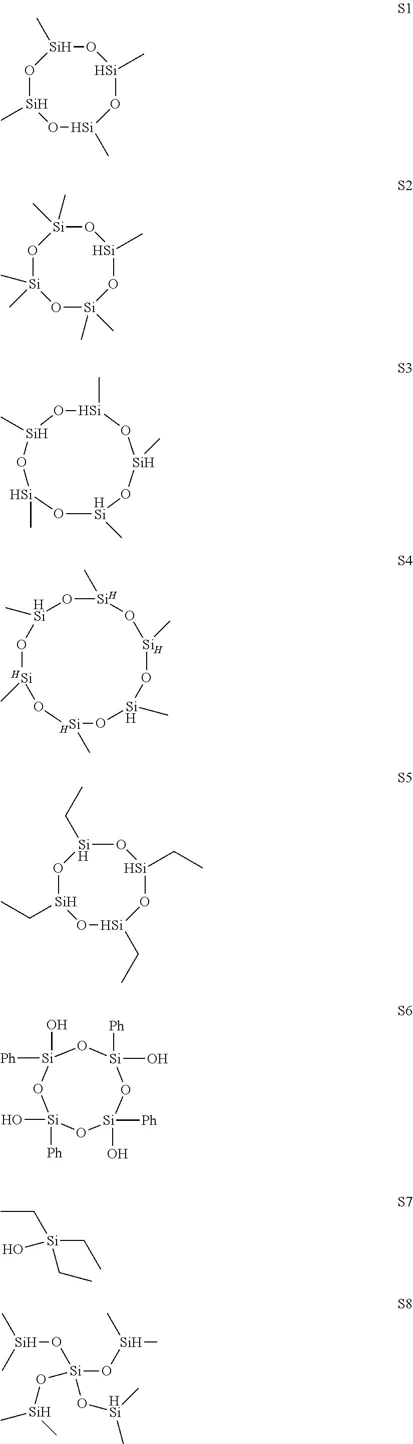

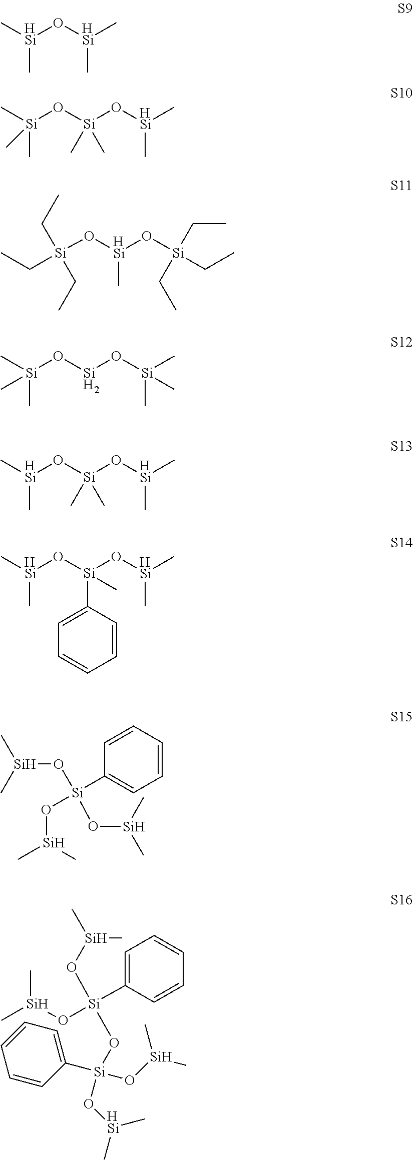

An example of the hydrophobic metal compound particles includes cage-type polyorganosilsesquioxane. In order to further enhance the adhesiveness with the substrate and the film-forming property, cage-type polyorganosilsesquioxane having a reactive group such as Si—H or Si—OH is preferable. Specific examples of the cage-type polyorganosilsesquioxane include the compounds represented by the following chemical formulae S17 to S19; however, the cage-type polyorganosilsesquioxane is not limited thereto.

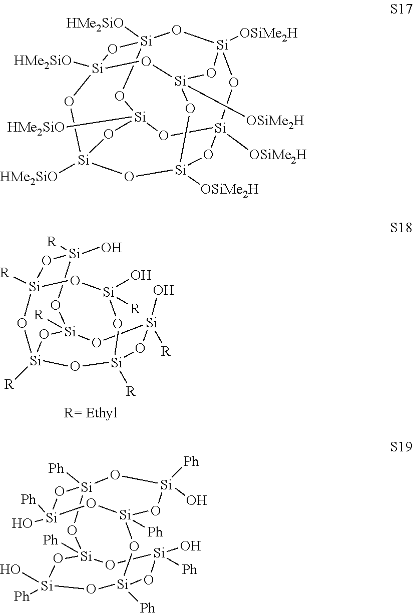

Although the hydrophobic metal compound particles may be used singly, or two or more kinds of the hydrophobic metal compound particles may be used in combination, however, it is preferable that two or more kinds of the hydrophobic metal compound particles are used in combination. Namely, the intermediate layer preferably contains at least two or more kinds of the hydrophobic metal compound particles. According to this constitution, the gas barrier property and the durability can be enhanced by imparting high hydrophobicity to the intermediate layer. The metal compound particles (A) contained in the intermediate layer are preferably two or more kinds of hydrophobic metal compound particles. As the hydrophobic metal compound particles, synthetics or commercial products may be used. Examples of the commercial products include SP series manufactured by Konishi Chemical Ind Co., Ltd. Specific examples of polyorganosilsesquioxane particles include water-dispersed products such as SP-1120 (H₂O) (organic group/methyl, particle diameter: 20 nm), SP-1160 (H₂O) (organic group/methyl, particle diameter: 60 nm), SP-2160 (H₂O) (organic group/phenyl, particle diameter: 60 nm), and SP-4120 (H₂O) (organic group/vinyl, particle diameter: 20 nm) and methyl ethyl ketone-dispersed products such as SP-1120 (MEK) (organic group/methyl, particle diameter: 20 nm), SP-1160 (MEK) (organic group/methyl, particle diameter: 60 nm), SP-6120 (MEK) (organic group/vinyl, particle diameter: 20 nm).

There may be used FOX series (registered trademark: the same description is hereinafter omitted) manufactured by Dow Corning Toray Co., Ltd. A specific example includes hydrogenated silsesquioxane such as FOX-14 (MIBK), FOX-15 (MIBK), and FOX-16 (MIBK).

(Method of Forming Intermediate Layer)

Although a method of forming the intermediate layer is not limited particularly, for example, it is preferable to use a method of dissolving or dispersing metal compound particles and, if necessary, a hydrophobic material and other additives in a solvent, preparing a coating liquid, coating the coating liquid onto the substrate by a roll coating method, a flow coating method, an inkjet method, a spray coating method, a printing method, a dip coating method, a cast film forming method, a bar coating method, a gravure printing method, or the like and drying the substrate.

When a solvent of the coating liquid for intermediate layer is an organic solvent-based solvent, it is preferable that the hydrophobic material is added in a state of being dissolved in the coating liquid. Specifically, the above wax or resin may be dissolved in the organic solvent for use. A photosensitive material or a thermosetting material used for a flat and smooth layer to be described later may be used.

When a solvent of an intermediate layer coating liquid is an aqueous solvent, it is preferable that the hydrophobic material is added in a state of being dispersed in the coating liquid. Specifically, emulsion of wax or resin is preferably used. Since wax or resin is required to melt in general coating and drying, a melting point or Tg of wax or resin is preferably not more than 120° C. and more preferably not more than 100° C. In order to obtain composition uniformity of the intermediate layer, dispersed particle diameter is preferably not more than 1 μm, and more preferably not more than 0.5 μm.

A deposition amount of a solid content of the intermediate layer is preferably in the range of 0.05 to g/m², more preferably 0.1 to 2 g/m², and still more preferably 0.3 to 1 g/m². When the coating is not less than 0.05 g/m², it is possible to form an adhesive region with a sufficient thickness in which the gas barrier layer is permeated into a void of the intermediate layer. When the coating is not more than 5 g/m², it is possible to suppress lowering of transparency due to unnecessary thickness not contributing to enhancement of adhesiveness. The solid content of the intermediate layer includes a metal compound particle, a hydrophobic material, and other additives.

Hereinabove, although the form in which the intermediate layer is formed by being coated with the coating liquid containing the metal compound particle mixed with the hydrophobic material has been described, in the formation of the intermediate layer of the present invention, a layer mainly composed of the metal compound particles is formed first, and thereafter the hydrophobic material is overcoated thereon, whereby the intermediate layer may be formed. In this case, the hydrophobic material may be overcoated as a liquid dispersed or dissolved in a solvent. Alternately, the hydrophobic material is volatilized under reduced pressure, if necessary, and may be overcoated by using a so-called gas phase method.

As surface roughness of the intermediate layer, a 10-point average roughness Rz defined in JIS B 0601 (2001) is preferably in the range of 1 to 200 nm, more preferably in the range of 5 to 120 nm, and still more preferably in the range of 35 to 50 nm. When the surface roughness Rz of the intermediate layer is not more than 200 nm, good adhesiveness between the intermediate layer and the second gas barrier layer can be maintained, and therefore it is preferable. When the surface roughness Rz of the intermediate layer is not less than 1 nm, a sufficient anchor effect (fixing effect) is obtained by the intermediate layer, so that adhesiveness of the second gas barrier layer to the intermediate layer is enhanced, and therefore it is preferable. In this case, “the surface roughness of the intermediate layer” indicates the surface roughness of an upper surface of the intermediate layer, that is, a surface on which the second gas barrier layer is formed.

[Overcoat Layer]

An overcoat layer may be formed on a gas barrier layer according to the present invention. The overcoat layer is formed of, for example, a material described in paragraphs [0127] to [0140] of Japanese Patent Application Laid-Open No. 2012-116101 or a commonly known material such as an organic inorganic composite material described as “ORMOCER (registered trademark)” in U.S. Pat. No. 6,503,634. The overcoat layer is formed by a method similar to that described in paragraph [0141] of Japanese Patent Application Laid-Open No. 2012-116101.

<<Applications of Gas Barrier Film>>

Gas barrier films of the present invention are applicable mainly for package of electronic devices and so on, or for gas barrier films used for display material such as an organic EL element, a solar cell, and a plastic substrate provided for liquid crystal, and for resin substrates used for various devices in which a gas barrier film is provided and various device elements.

The gas barrier film of the present invention is preferably applicable for various sealing materials and films.

An organic EL element will be described as an example of an electronic device equipped with the gas barrier film of the present invention.

[Organic EL Element]

When the gas barrier film of the invention is used in an organic EL element, the gas barrier film is preferably transparent and may be used as a substrate (also referred to as a support).

Namely, a transparent conductive thin film such as ITO as a transparent electrode, for example, is provided on the gas barrier film of the present invention to constitute a resin support used for organic EL element.

Then, the ITO transparent conductive film is provided as an anode, on a resin support for organic EL element, a porous semiconductor layer is provided on this anode, and a cathode composed of a metal film is further formed to produce the organic EL element. The same or another sealing material is layered on this element, and the foregoing gas barrier film support adheres to circumference thereof to seal the element, whereby the organic EL element can be sealed. As a result, the influences of water vapor of outside air and gas such as oxygen on the element can be suppressed.

The resin support for the organic EL element is obtained by forming a transparent conductive thin film on a ceramic layer of the gas barrier film prepared as described above (herein, the ceramic layer may indicate a silicon oxide layer formed via a modifying treatment of a polysilazane layer).

A transparent conductive thin film can be formed by a vacuum vapor deposition method, a sputtering method or the like, and also prepared by a coating method such as a sol-gel method employing metal alkoxide of indium, tin or the like.

Further, the transparent conductive thin film is preferably a transparent conductive thin film having a film thickness of 0.1 to 1,000 nm.

Next, each layer of organic EL element materials constituting the organic EL element will be described.

(Configuration of Organic EL Element)

Preferred embodiments of the organic EL element will be described.

The organic EL element is not specifically limited, and may be an element in which an anode, a cathode, and at least one light emitting layer sandwiched between the anode and the cathode are provided and which emits light by application of voltage.

Preferred specific examples of layer configuration for the organic EL element will be hereinafter described.

anode/light emitting layer/cathode anode/hole transport layer/light emitting layer/cathode

anode/light emitting layer/electron transport layer/cathode

anode/hole transport layer/light emitting layer/electron transport layer/cathode

anode/anode buffer layer (hole injection layer)/hole transport layer/light emitting layer/electron transport layer/cathode buffer layer (hole injection layer)/cathode

Hereinafter, material constituting each of these layers will be described.

(Transparent Electrode (First Electrode))

A transparent electrode as a cathode or an anode is not particularly limited, and can be selected depending on element configuration, but the transparent electrode is preferably used as an anode. When being used as an anode, it is preferably an electrode transmitting light having a wavelength of 380 to 800 nm.

Usable examples of material include transparent conductive metal oxide such as indium tin oxide (ITO), SnO₂, and ZnO, a metal thin film formed of gold, silver, platinum or the like, metal nanowire, and carbon nanotube.

Also usable are a conductive polymer selected from the group consisting of derivatives of polypyrrole, polyaniline, polythiophene, polythienylene vinylene, polyazulene, polyisothianaphthene, polycarbazole, polyacetylene, polyphenylene, polyphenylene vinylene, polyacene, polyphenylacetylene, polydiacetylene and polynaphthalene. Further, these conductive compounds may be also used in combination to produce a transparent electrode.

(Counter Electrode (Second Electrode))

The counter electrode may be a layer consisting of a conductive material, but in addition to a material exhibiting conductivity, a resin to support this material may be used in combination. As a conductive material used for a counter electrode, those containing metal, alloy, an electric conductive compound, and a mixture thereof having a small work function (that is, the same or less than 4 eV) as an electrode material are used.

Specific examples of such an electrode material include sodium, a sodium potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and a rare earth metal.

Among these, from the viewpoint of electron extraction performance and resistance to oxidation, preferable is a mixture of each of these metals and the second metal as a stable metal having a larger work function than that of the foregoing metal such as a magnesium/silver mixture, a magnesium/aluminum mixture, a magnesium/indium mixture, an aluminum/aluminum oxide (Al₂O₃) mixture, a lithium/aluminum mixture, and aluminum.

A thin film as a counter electrode can be prepared via vapor deposition or sputtering of this electrode material. Further, the film thickness is generally selected from the range of 10 nm to 5 μm, and preferably selected from the range of 50 to 200 nm.

Further, a counter electrode may be formed of metal such as gold, silver, copper, platinum, rhodium, ruthenium, aluminum, magnesium or indium, nano particles formed of carbon, nanowires formed of carbon, or a nano structure material of carbon. When a dispersion of nanowires formed of carbon is used, a transparent counter electrode exhibiting high conductivity can be prepared by a coating method, and therefore it is preferable.

When making the counter electrode side to be light-transparent, for example, a light-transparent counter electrode can be made by providing a layer formed of a conductive light-transparent material cited in the description of the foregoing transparent electrode, after preparing a film made of a conductive material suitable for a counter electrode such as aluminum, aluminum alloy, silver, and a silver compound, which has a film thickness of about 1 to 20 nm.

((Metal Nanowire))

In the organic EL element, conductive fiber can be used, and usable examples of conductive fiber include metal-coated organic or inorganic fiber, conductive metal oxide fiber, metal nanowire, carbon fiber, and carbon nanotube, but metal nanowire is preferable.

The metal nanowire generally means a linear structure made from metal elements as main constituting elements. Specifically, the metal nanowire of the present invention means a linear structure having a diameter of several nanometers.

The metal nanowire preferably has a mean length of 3 μm or more, more preferably has a mean length of 3 μm to 500 μm, and particularly preferably 3 μm to 300 μm in order to prepare a long conductive path with a single metal nanowire, and to exhibit appropriate light scattering performance. In addition, the length preferably has a relative standard deviation of 40% or less.

Further, the average diameter is preferably small in view of transparency, and on the other hand, it is preferably large in view of conductivity. In the present invention, the metal nanowire preferably has an average diameter of 10 nm to 300 nm, and more preferably has an average diameter of 30 nm to 200 nm. In addition, the diameter preferably has a relative standard deviation of 20% or less.

The metal composition of the metal nanowire is not specifically limited, and can be composed of at least one metal as a noble metal element or less noble metal element, but preferably contains at least one metal selected from the group consisting of gold, platinum, silver, palladium, rhodium, iridium, ruthenium, osmium, iron, cobalt, copper and tin, and more preferably contains at least silver in view of conductivity.

Silver and noble metals other than silver are also preferably contained in order to simultaneously realize the conductivity and stability such as resistance to sulfuration or oxidation of metal nanowires, and resistance to migration. When the metal nanowire contains two or more kinds of metal elements, for example, the surface and the inside of the metal nanowire may be different from each other in terms of metal composition, and the whole metal nanowire may have the same metal composition.

A method of manufacturing the metal nanowire is not specifically limited, a commonly known manufacturing method such as a liquid phase method or a vapor phase method is usable, for example.

As a method of manufacturing Ag nanowire cited are, for example, Adv. Mater., 2002, 14, 833-837 and Chem. Mater., 2002, 14, 4736-4745. As a method of manufacturing Au nanowire cited is Japanese Patent Application Laid-Open No. 2006-233252. As a method of manufacturing Cu nanowire cited is Japanese Patent Application Laid-Open No. 2002-266007. As a method of manufacturing Co nanowire cited is Japanese Patent Application Laid-Open No. 2004-149871. Specifically, according to the foregoing method of manufacturing Ag nanowire as described in Adv. Mater. and Chem. Mater., Ag nanowire can be prepared simply in an aqueous system, and further, since electrical conductivity of silver is the highest among all metals, it is preferably applicable as a method of manufacturing silver nanowire.

(Hole Transport Layer/Electron Block Layer)

A hole transport layer is formed of a hole transport material having a function of transporting a hole, and in a broad sense, a hole injection layer and an electron block layer are included in the hole transport layer. Single or plural hole transport layers may be provided.

A material constituting the above layers has any one of a hole injection property, hole transportability, and an electron barrier property and may be an organic substance or an inorganic substance, and, for example, PEDOT (poly-3,4-ethylenedioxythiopehen) such as product name: Baytron P (registered trademark) manufactured by H. C. Starck-V TECH Ltd., polyaniline and doped material thereof, a cyan compound described in WO 06/19270 and so on may be used.

A hole transport layer having such a rectification effect that electrons do not flow to the anode side is also called an electron block layer, and it is preferable to use a hole transport layer having such a function. Examples of such a material include a triarylamine based compound disclosed in Japanese Patent Application Laid-Open No. H5-271166, and metal oxide such as molybdenum oxide, nickel oxide, and tungsten oxide.

The hole transport layer can be formed of the hole transport material by a commonly known method such as a vacuum vapor deposition method or a solution coating method. Among the commonly known methods, the solution coating method including a spin coating method, a casting method, and an ink-jet method is preferable.

Although a film thickness of the hole transport layer is not limited particularly, the film thickness is usually approximately 5 nm to 5 μm, and preferably 5 to 200 nm. The hole transport layer may have a single layer structure made of one or two or more kinds of the foregoing materials.

(Electron Transport Layer/Hole Block Layer)

An electron transport layer is formed of an electron transport material having a function of transporting an electron, and in a broad sense, an electron injection layer and a hole block layer are included in the electron transport layer. Single or plural electron transport layers may be provided.

A material of the electron transport layer may have a function of transmitting electrons injected by a cathode to a light emitting layer, and there may be used octaazaporphyrin, and a perfluoro form of a p-type semiconductor such as perfluoropentacene and perfluorophthalocyanine.

An electron transport layer having such a rectification effect that holes do not flow to the cathode side is also called a hole block layer, and it is preferable that an electron transport layer having such a function is used.

Usable examples of material thereof include a phenanthrene based compound such as bathocuproine; n-type semiconductor material such as naphthalene tetracarboxylic acid anhydride, naphthalene tetracarboxylic acid diimide, perylene tetracarboxylic acid anhydride, and perylene tetracarboxylic acid diimide; n-type inorganic oxide such as titanium oxide, zinc oxide, and gallium oxide; an alkali metal compound such as lithium fluoride, sodium fluoride, and cesium fluoride.

The electron transport layer can be formed of the electron transport material by a commonly known method such as a vacuum vapor deposition method or a solution coating method. Among the commonly known methods, the solution coating method including a spin coating method, a casting method, and an ink-jet method is preferable.

Although a film thickness of the electron transport layer is not limited particularly, the film thickness is usually approximately 5 nm to 5 μm, and preferably 5 to 200 nm. The hole transport layer may have a single layer structure made of one or two or more kinds of the foregoing materials.

(Light Emitting Layer)

The light emitting layer in the organic EL element may be a layer emitting light by recombining electrons and holes injected from electrodes (cathode and anode) or the electron transport layer and the hole transport layer, and a light emitting portion may be inside the light emitting layer or an interface between the light emitting layer and an adjacent layer thereof.

The light emitting layer of the organic EL element preferably contains the following dopant compound (light emitting dopant) and host compound (light emitting host). Consequently, light emitting efficiency can be further enhanced.

((Light Emitting Dopant))

The light emitting dopants can be roughly classified into two kinds, one of which is a fluorescent dopant emitting fluorescence and the other of which is a phosphorescent dopant emitting phosphorescence.

Typical examples of the fluorescent dopant include a coumalin type dye, a pyrane type dye, a cyanine type dye, a chroconium type dye, a squalium type dye, an oxobenzanthracene type dye, a fluorescein type dye, a rhodamine type dye, a pyrylium type dye, a perylene type dye, a stilbene type dye, a polythiophene type dye and a rare-earth complex type fluorescent compound.

Typical examples of the phosphorescent dopant are preferably a complex compound containing a metal included in Groups 8, 9 or 10 of periodic table of elements, and more preferably an iridium compound and an osmium compound. Among them, the iridium compounds are most preferable. As the light emitting dopant, plural kinds of compounds may be mixed for use.

((Light Emitting Host))

The light emission host (also simply referred to as host) is a compound having the highest mixing ratio (mass) in the light emitting layer formed of two or more kinds of compounds, and a compound other than the host is referred to as a “dopant compound (also simply referred to as dopant)”. For example, the light emitting layer is consisting of two kinds of compounds, namely, Compound A and Compound B, and when the mixing ratio A:B is 10:90, Compound A is the dopant compound and compound B is the host compound. The light emitting layer is consisting of three kinds of compounds, namely, Compounds A, B, and C, and when the mixing ratio of A:B:C is 5:10:85, Compounds A and B are the dopant compounds and Compound C is the host compound.

Although the structure of the light emission host is not limited particularly, representative examples include a compound having a basic skeleton of a carbazole derivative, a triarylamine derivative, an aromatic borane derivative, a nitrogen-containing heterocyclic compound, a thiophene derivative, a furan derivative, an oligoarylene compound, or the like, a carboline derivative, and a diazacarbazole derivative (the diazacarbazole derivative represents a compound formed by substituting at least one carbon atom of a hydrocarbon ring constituting a carboline ring of a carboline derivative by a nitrogen atom). Among them, the carboline derivative, the diazacarbazole derivative, and so on are preferably used.

The light emitting layer can be formed by film-forming with the above compounds by a commonly known thin-film forming method such as a vacuum deposition method, a spin coat method, a cast method, an LB method, and an ink jet method. Although the film thickness of the light emitting layer is not limited particularly, the film thickness is usually selected in the range of 5 nm to 5 μm and preferably 5 to 200 nm. The light emitting layer may have a single layer structure made of one or two or more kinds of the dopant compounds or the host compounds, or a laminated structure constituted of plural layers having the same or heterogeneous composition.

(Other Layers)

In order to improve energy conversion efficiency, or to improve element lifetime, the configuration in which various middle layers are provided in an element may be used.

Examples of the middle layer include a hole block layer, an electron block layer, a hole injection layer, an electron injection layer, an exciton block layer, a UV absorbing layer, a light reflection layer, and a wavelength conversion layer.

(Film Formation Method/Surface Treatment Method)

An example of a method of manufacturing each of the foregoing transport layers/electrodes includes a vapor deposition method, and a coating method such as a casting method and a spin coat method, as described above.

Among the manufacturing methods, the coating method is preferable in terms of high manufacturing speed.

A coating method employed in this case is not limited, and examples thereof include a spin coating method, a solution casting method, a dip coating method, a blade coating method, a wire bar coating method, a gravure coating method, and a spray coating method. Further, patterning can be also conducted by each of printing methods such as an ink-jet method, a screen printing method, a letterpress printing method, an intaglio printing, an offset printing method, or a flexographic printing method.

(Patterning)

Methods and processes of patterning an electrode, a light emitting layer, a hole transport layer, an electron transport layer and so on are not limited particularly, and commonly known methods are suitably applicable.

When a material contained in each layer is a soluble material, only undesired portions may be removed after coating the entire surface via die coating, dip coating, or the like, or direct patterning may be conducted during coating by using an ink-jet method, a screen printing method or the like.

In the case of an insoluble material such as an electrode material, mask vapor deposition can be conducted during vacuum deposition of an electrode, and pattering can be also conducted by a commonly known method such as etching and lift-off. Further, a pattern having been prepared on another substrate may be transferred to prepare the pattern.

### EXAMPLES

Hereinafter, the present invention is described specifically by referring to examples, however, the present invention is not limited thereto. In the examples, the term “%” is used. Unless particularly mentioned, this represents “% by mass”.

### Evaluation 1: Evaluation of Durability of Gas Barrier Film

### Example 1-1

### Preparation of Substrate (a)

As a thermoplastic resin substrate (support), a polyester film (KDL 86W produced by Teij in Dupont Films Japan Ltd.) having a thickness of 125 μm, whose surfaces each are subjected to an easy adhesion treatment, was used as a substrate as it is. In the surface roughness of the substrate (a) measured in conformity to the method defined in JIS B 0601 (2001), the surface roughness Ra was 4 nm, and the surface roughness Rz was 320 nm.

The surface roughness was measured by employing an AFM (atomic force microscope) SPI3800N DFM, manufactured by SII Inc. Measurement range of a single measurement was 80 μm×80 μm, and the measurement was conducted three times while changing measurement locations, values of Ra and the 10-point average roughness Rz obtained by each measurement were averaged to be designated as a measured value.

[Formation of First Gas Barrier Layer]

(Formation of Polysilazane Layer)

A polysilazane-containing coating liquid prepared as follows was coated onto the substrate by using a spin coater under the condition allowing that the film thickness after drying was 100 nm. The drying condition included 2 min at 100° C.

<Preparation of Polysilazane-Containing Coating Liquid>

In the preparation of the polysilazane-containing coating liquid, a dibutyl ether solution containing 20% by mass of non-catalytic perhydropolysilazane (NN120-20, produced by AZ electronic materials Co., Ltd.), and a dibutyl ether solution containing N,N,N′,N′-tetramethyl-1,6-diaminohexane as an amine catalyst and 19% by mass of perhydropolysilazane (NAX120-20, produced by AZ electronic materials Co., Ltd.) were mixed at a mass ratio of 4:1 and then prepared to 1% by mass with respect to a solid content of the coating liquid. The prepared solution was suitably diluted with dibutyl ether according to set film thickness, whereby the coating liquid was prepared.

(Vacuum Ultraviolet Ray Irradiation Treatment)

A polysilazane layer coating was formed as described above, and then vacuum ultraviolet ray irradiation treatment was applied in accordance with the following method, and a gas barrier layer was formed. Details of treatment conditions are shown in Tables 1-1 and 1-2.

<Condition for Vacuum Ultraviolet Ray Irradiation and Measurement of Irradiation Energy>

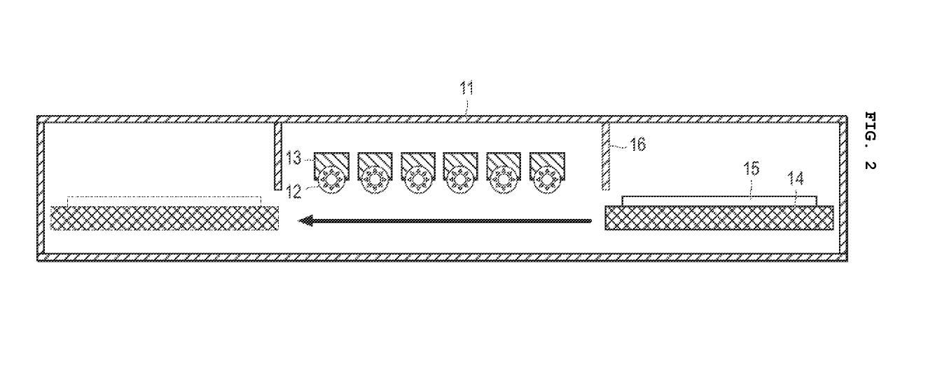

The vacuum ultraviolet ray irradiation was performed by using a device described in the cross-sectional pattern diagram of FIG. 2.

In FIG. 2, reference numeral 11 is an apparatus chamber, and a suitable amount of nitrogen and oxygen is supplied from a gas inlet (not shown) to the inside and discharged through a gas outlet (not shown), whereby water vapor is substantially removed from the inside of the chamber, so that oxygen concentration can be maintained at a predetermined concentration. Reference numeral 12 is a Xe excimer lamp irradiating a vacuum ultraviolet ray of 172 nm and having a double-tubular structure, and reference numeral 13 is a holder of the examiner lamp and serves as an external electrode. Reference numeral 14 is a sample stage. The sample stage 14 can move back and forth horizontally at a predetermined speed within the apparatus chamber 11 by a moving means (not shown). Further, the sample stage 14 can be maintained at a predetermined temperature by a heating means (not shown). Reference numeral 15 is a sample with a polysilazane coating layer formed thereon. Height of the sample stage 14 is adjusted such that, when the sample stage 14 moves horizontally, the shortest distance between a coating layer surface of the sample and a tubular surface of the excimer lamp is 3 mm. Reference numeral 16 is a light shielding plate, and it prevents irradiation of a vacuum ultraviolet ray on a coating layer on the sample during aging of the Xe excimer lamp 12.

The energy irradiated on the coating layer surface of the sample by the vacuum ultraviolet ray irradiation process was measured by using a ultraviolet integrated actinometer C8026/H8025 UV POWER METER manufactured by Hamamatsu Photonics K.K. and a sensor head of 172 nm. For the measurement, the sensor head was set at the center of the sample stage 4 such that the shortest distance between the tubular surface of the Xe excimer lamp and the measurement surface of the sensor head is 3 mm. Further, nitrogen and oxygen were fed such that the atmosphere inside the apparatus chamber 11 has the same oxygen concentration as the vacuum ultraviolet ray irradiation process and the sample stage 4 was moved at the rate of 0.5 m/min to perform the measurement. Before the measurement, to stabilize the illuminance of the Xe excimer lamp 2, aging time of 10 min was allowed after lighting the Xe excimer lamp 12. After that, the sample stage 4 is moved, and the measurement was initiated.

Based on the irradiation energy obtained from the above measurement, an adjustment was made to have the irradiation energy shown in Tables 1-1 and 1-2 by adjusting the movement rate of the sample stage 14. Meanwhile, for the vacuum ultraviolet ray irradiation, it was performed after aging time of 10 min, similarly to the measurement of irradiation energy.

The first gas barrier layer was formed as described above.

[Formation of Intermediate Layer (ML1)]

As described below, an intermediate layer (ML1) was formed on the first gas barrier layer formed as described above.

As the metal compound particle, Snowtex (registered trademark; hereinafter, the same description will be omitted) N (particle diameter: 10 to 20 nm) manufactured by Nissan Chemical Industries, Ltd., which is the hydrophilic metal compound particle, was used, and as emulsion containing the hydrophobic material, soap free acrylic emulsion AE 986 B (particle diameter: 60 nm, Tg: 2° C.) manufactured by EMULSION TECHNOLOGY CO., LTD. was used. Further, as a surfactant, Surfynol (registered trademark; hereinafter, the same description will be omitted) 465 manufactured by Air Products and Chemicals, Inc. was used. The hydrophilic metal compound particle, the hydrophobic material, and the surfactant were mixed at a mass ratio of 80.0/19.8/0.2 as the solid contents and then diluted with pure water, and a coating liquid having a solid content of 10% by mass was prepared.

This coating liquid was coated onto the first gas barrier layer with a dry deposition amount of 0.5 g/m² and then dried at 120° C. for 2 minutes, and the intermediate layer (ML1) was formed.

For the upper surface of the intermediate layer (ML1) formed as described above, that is, a surface on which the second gas barrier layer is formed, regarding the surface roughness measured in conformity to the method defined in JIS B 0601 (2001), the 10-point average roughness Rz was 80 nm. The surface roughness was measured by a method similar to that used in the measurement of the substrate (a). Each surface roughness of the intermediate layers (ML2 to 10) to be described below was measured in a similar manner, and the results are shown in Tables 1-1 and 1-2.

[Formation of Second Gas Barrier Layer]

The second gas barrier layer was formed on the intermediate layer (ML1) under the same conditions as those in the first gas barrier layer.

The gas barrier film was manufactured as described above.

### Example 1-2

A gas barrier film was manufactured in a similar manner to Example 1-1, except that an intermediate layer (ML2) in which the kind of the hydrophilic metal compound particle contained in the intermediate layer was changed to Snowtex PS-M (particle diameter: 80 to 120 nm) manufactured by Nissan Chemical Industries, Ltd. was formed.

### Example 1-3

A gas barrier film was manufactured in a similar manner to Example 1-2, except that an intermediate layer (ML3) in which the mass ratio of the hydrophilic metal compound particle, the hydrophobic material, and the surfactant contained in the intermediate layer was changed to 70.0/29.8/0.2 was formed.

### Example 1-4

A gas barrier film was manufactured in a similar manner to Example 1-1, except that respective components contained in the intermediate layer and the mass ratio of the respective components were changed. The components contained in the intermediate layer (ML4) and a component ratio are as follows.

As the metal compound particle, IPA-ST (isopropanol dispersion, particle diameter: 10 to 20 nm) manufactured by Nissan Chemical Industries, Ltd., which is the hydrophilic metal compound particle, was used, and as the hydrophobic metal compound particle, a compound (polyorganosiloxane) represented by the foregoing chemical formula S1 was used. The hydrophilic metal compound particle and the hydrophobic metal compound particle were mixed at a mass ratio of 80.0/20.0 as the solid contents and diluted with isopropanol, and a coating liquid having a solid content of 10% by mass was prepared.

### Example 1-5

A gas barrier film was manufactured in a similar manner to Example 1-1, except that respective components contained in the intermediate layer, the mass ratio of the respective components, and the method of forming the intermediate layer were changed. The components contained in the intermediate layer (ML5) and a method of forming the intermediate layer (ML5) are as follows.

As the metal compound particle, IPA-ST (isopropanol dispersion, particle diameter: 10 to 20 nm) manufactured by Nissan Chemical Industries, Ltd., which is the hydrophilic metal compound particle, was used, and as the hydrophobic metal compound particle, a compound (polyorganosiloxane) represented by the foregoing chemical formula S2 was used.

First, on the first gas barrier layer, a solution containing only the hydrophilic metal compound particle was coated onto a substrate with a dry deposition amount of 0.5 g/m² and then dried at 120° C. for 2 minutes.

Then, in order to impart hydrophobicity to the intermediate layer, a solution prepared by diluting methyl hydrogen silicone oil KF-9901 manufactured by Shin-Etsu Chemical Co., Ltd. with methyl ethyl ketone was coated onto a layer containing only the metal compound particle so that the dry deposition amount was 0.03 g/m² and then dried at 120° C. for 2 minutes, and the intermediate layer (ML5) was formed. Namely, the intermediate layer (ML5) was formed so that the mass ratio of the hydrophilic metal compound particle/the hydrophobic metal compound particle was 94.3/5.7 as the solid contents.

### Example 1-6

A gas barrier film was manufactured in a similar manner to Example 1-1, except that only the hydrophobic metal compound particle was used as the metal compound particle contained in the intermediate layer, and, in addition, the hydrophobic material was not added. The components contained in the intermediate layer (ML6) and a method of forming the intermediate layer (ML6) are as follows.

As the hydrophobic metal compound particle, silsesquioxane SP-1120 (MEK) (particle diameter: 20 nm) manufactured by Konishi Chemical Ind Co., Ltd. was used. The hydrophobic metal compound particle was diluted with methyl isobutyl ketone to give a solid content of 5% by mass, and, thus, to prepare a coating liquid. This coating liquid was coated onto the first gas barrier layer with a dry deposition amount of 0.2 g/m² and then dried at 120° C. for 2 minutes, and the intermediate layer (ML6) was formed. Namely, the intermediate layer was formed so that the hydrophobic metal compound particle was 100% by mass as the solid content.

### Example 1-7

A gas barrier film was manufactured in a similar manner to Example 1-6, except that two kinds of the hydrophobic metal compound particles contained in the intermediate layer were used. The components contained in the intermediate layer (ML7) and a method of forming the intermediate layer (ML7) are as follows.

As the hydrophobic metal compound particles, silsesquioxane SP-1120 (MEK) (particle diameter: 20 nm) manufactured by Konishi Chemical Ind Co., Ltd. and hydrogen silsesquioxane (FOX (registered trademark)-14 (15 wt % MIBK solution) manufactured by Dow Corning Toray Co., Ltd.) were used. SP-1120 (MEK) and hydrogen silsesquioxane were mixed and dispersed so that the ratio between them was 70/30 (SP-1120 (MEK)/hydrogen silsesquioxane), and a coating liquid was prepared. This coating liquid was coated onto the first gas barrier layer with a dry deposition amount of 0.5 g/m² and then dried at 120° C. for 2 minutes, and the intermediate layer (ML7) was formed.

### Example 1-8

A gas barrier film was manufactured in a similar manner to the gas barrier film of Example 1-6, except that the substrate was changed to the following substrate (b).

### Preparation of Substrate (b)

By using a polyester film (super-low heat shrinkage PET Q83, produced by Teijin Dupont Films Japan Ltd.) having a thickness of 125 μm, whose surfaces each are subjected to an easy adhesion treatment, as a thermoplastic resin substrate (that is, support), a bleed out preventing layer is provided on one surface, and a flat and smooth layer is provided on an opposite surface, and the resultant is used as a substrate (b).

<Formation of Bleed Out Preventing Layer>

After a UV curable organic/inorganic hybrid hard coat material OPSTAR (registered trademark; hereinafter, the same description will be omitted) 27535 produced by JSR Corporation was coated on one surface of the foregoing thermoplastic resin substrate under the condition to have a dry film thickness of 4.0 μm, curing was conducted under the curing conditions including irradiation energy amount of 1.0 J/cm², air atmosphere, and use of a high pressure mercury lamp; and the drying conditions of 80° C. for 3 minutes to form a bleed out preventing layer.

<Formation of Flat and Smooth Layer>

Subsequently, a UV curable type organic/inorganic hybrid hard coating material OPSTAR Z7501, which is produced by JSR Corporation, was coated on a surface opposite to the surface on which the bleed out preventing layer of the thermoplastic resin substrate is formed, under the condition to have a film thickness of 4.0 μm after drying, followed by drying under the drying conditions of 80° C. for 3 minutes, and curing was subsequently conducted under the curing conditions including irradiation energy amount of 1.0 J/cm², air atmosphere, and use of a high pressure mercury lamp to form the flat and smooth layer.

The surface roughness Ra of the obtained flat and smooth layer as measured in conformity to the method described in JIS B 0601 (2001) was about 1 nm. Further, Rz was 20 nm. The surface roughness was measured by a similar method to that used in the measurement of the substrate (a). A coating surface of the first gas barrier layer was a surface of the flat and smooth layer.

### Example 1-9

A gas barrier film was manufactured in a similar manner to the gas barrier film of Example 1-4, except that the substrate was changed to the following substrate (c).

### Preparation of Substrate (c)

By using a transparent polyimide film (NEOPRIM L, produced by Mitsubishi Gas Chemical Company, Inc.) having a thickness of 200 μm, whose surfaces each are subjected to an easy adhesion treatment, as a heat resistant substrate, a flat and smooth layer is provided on both surfaces of the substrate, and the resultant is used as a substrate (c).

(Formation of Flat and Smooth Layer)

<Preparation of Coating Liquid for Flat and Smooth Layer>

8.0 g of trimethylol propane triglycidyl ether (EPOLIGHT

(registered trademark) 100MF, manufactured by KYOEISHA CHEMICAL Co., LTD.), 5.0 g of ethylene glycol glycidyl ether (EPOLIGHT (registered trademark) 40E, manufactured by KYOEISHA CHEMICAL Co., LTD.), 12.0 g of silsesquioxane having an oxetanyl group: OX-SQ-H (manufactured by Toagosei Company, Limited), 32.5 g of 3-glycidyoxypropyltrimethoxysilane, 2.2 g of Al (III) acetyl acetonate, 134.0 g of methanol silica sol (manufactured by Nissan Chemical Industries, Ltd., solid matter content of 30% by mass), 0.1 g of BYK333 (manufactured by BYK Japan KK, silicone-based surface active agent), 125.0 g of butyl cellosolve, and 15.0 g of 0.1 mol/L aqueous solution of hydrogen chloride were mixed with one another and fully stirred. The resultant was deaerated by keeping it again at room temperature to obtain a coating liquid for a flat and smooth layer.

<Formation of Flat and Smooth Layer 1>

Corona discharge treatment was performed for one surface of the heat resistant substrate according to a standard method, the coating liquid for a flat and smooth layer was coated under the condition that film thickness is 4.0 μm after drying, and it was dried for 3 min at 80° C. By performing a heating treatment for 10 min at 120° C., the flat and smooth layer 1 was formed.

<Formation of Flat and Smooth Layer 2>

The flat and smooth layer 2 was formed on a surface of the heat resistant substrate, which is opposite to the surface on which the flat and smooth layer 1 is formed, in the same manner as the method of forming the flat and smooth layer 1.

The surface roughness of the formed flat and smooth layer 1 and the flat and smooth layer 2 was measured by the method described in JIS B 0601 (2001). As a result, the surface roughness Ra is 2 nm, and the surface roughness Rz was 25 nm. The surface roughness was measured by a method similar to that used in the measurement of the substrate (a). A coating surface of the first gas barrier layer was a surface of the flat and smooth layer 1.

### Example 1-10

A gas barrier film was manufactured in a similar manner to the gas barrier film of Example 1-6, except that the substrate was changed to the following substrate (d).

### Preparation of Substrate (d)

The substrate (d) was prepared in the same manner as the preparation of the substrate (c) except that SIL PLUS (registered trademark) H100 with thickness of 100 μm manufactured by Nippon Steel & Sumikin Chemical Co., Ltd, which is a film having silsesquioxane with an organic and inorganic hybrid structure as a main skeleton, was used as a heat resistant substrate instead of a transparent polyimide film (NEOPRIML, produced by Mitsubishi Gas Chemical Company, Inc.) having a thickness of 200 μm, whose surfaces each are subjected to an easy adhesion treatment. Meanwhile, as a result of measuring the surface roughness of the flat and smooth layer 1 and the flat and smooth layer 2 of the substrate (d) in conformity to the method defined in JIS B 0601 (2001), Ra was 1 nm, and Rz was 20 nm. The surface roughness was measured by a method similar to that used in the measurement of the substrate (a). The coating surface of the first gas barrier layer was the surface of the flat and smooth layer 1.

### Comparative Example 1-1

A gas barrier film was manufactured in a similar manner to the gas barrier film of Example 1-8, except that the intermediate layer was not formed. Namely, after the formation of the first gas barrier layer, the second gas barrier layer was continuously formed as it is.

### Comparative Example 1-2

A gas barrier film was manufactured in a similar manner to the gas barrier film of Example 1-1, except that the intermediate layer was not formed. Namely, after the formation of the first gas barrier layer, the second gas barrier layer was continuously formed as it is.

### Comparative Example 1-3

A gas barrier film was manufactured in a similar manner to the gas barrier film of Example 1-1, except that the intermediate layer is not formed, and integrated irradiation energy was changed to 4500 mJ/cm² as a VUV ray irradiation condition of the gas barrier layer. Namely, after the formation of the first gas barrier layer, the second gas barrier layer was continuously formed as it is.

### Comparative Example 1-4

A gas barrier film was manufactured by forming an intermediate layer (ML8) in a similar manner to Example 1-5, except that the intermediate layer does not contain a compound as the hydrophobic metal compound particle represented by the foregoing chemical formula S2. Namely, the intermediate layer (ML8) does not contain the hydrophobic metal compound particle and the hydrophobic material and is hydrophilic.

### Comparative Example 1-5

A gas barrier film was manufactured in a similar manner to Example 1-1, except that respective components contained in the intermediate layer, the mass ratio of the respective components, and the method of forming the intermediate layer were changed. The components contained in the intermediate layer (ML9) and the method of forming the intermediate layer (ML9) are as follows.

As the hydrophilic metal compound particle, Snowtex 0 (particle diameter: 10 to 20 nm) manufactured by Nissan Chemical Industries, Ltd. was used, and as a water-soluble binder, poval (registered trademark) R-1130 manufactured by Kuraray Co., Ltd. was used. As a surfactant, Surfynol 465 manufactured by Air Products and Chemicals, Inc. was used. The hydrophilic metal compound particle, the water-soluble binder, and the surfactant were mixed at a mass ratio of 60.0/39.8/0.2 as the solid contents and then diluted with pure water, and a coating liquid having a solid content of 10% by mass was prepared.

This coating liquid was coated onto the substrate with a dry deposition amount of 0.5 g/m² and then dried at 120° C. for 2 minutes, and the intermediate layer (ML9) was formed. Namely, the intermediate layer (ML9) does not contain the hydrophobic metal compound particle and the hydrophobic material and is hydrophilic.

<<Evaluation of Water Vapor Barrier Property>>

(Apparatus for Preparation of Sample for Evaluation of Water Vapor Barrier Property)

Deposition apparatus: Vacuum deposition apparatus JEE-400 manufactured by JEOL, Ltd.

Constant temperature and humidity oven: Yamato Humidic Chamber IG 47 M

(Raw Material)

Metal to be corroded by reaction with moisture: calcium (particle)

Water vapor impermeable metal: aluminum (φ: 3 to 5 mm, particle)

(Preparation of Sample for Evaluation of Water Vapor Barrier Property)

Each gas barrier layer surface of the gas barrier films manufactured in Examples 1-1 to 1-10 and Comparative Examples 1-1 to 1-5 was vapor-deposited with metal calcium to have a size of 12 mm×12 mm by passing through a mask using a vacuum deposition apparatus (JEE-400 made by JEOL, Ltd.).

Thereafter, the mask was removed while keeping the vacuum condition, and aluminum was deposited on a whole one surface of the sheet for pseudo-sealing. Subsequently, the vacuum condition was released. The pseudo-sealed sample was immediately transferred to a dry nitrogen gas atmosphere, and then, a quartz glass having a thickness of 0.2 mm was adhered onto the aluminum vapor-deposited surface using an ultraviolet curing resin for sealing (manufactured by Nagase ChemteX Corporation), and an ultraviolet ray was irradiated for adhesion and curing of the resin for main sealing. As a result, a sample for evaluating water vapor barrier property was prepared.

(Evaluation Method)

An obtained sample was stored under high temperature and humidity of 60° C. and 90% RH, and a state in which metal calcium corrodes due to the storage time was observed. The observation was performed per 5 hours, and an area corresponding to corroded metal calcium with respect to a metal calcium vapor deposition area having a size of 12 mm×12 mm was calculated in terms of %. Time when the area corresponding to corroded metal calcium exceeds 20% is an index of time when progression of corrosion starts, that is, when the gas barrier layer is significantly peeled from a layer immediately below the gas barrier layer, and the results are shown in Tables 1-1 and 1-2. In the term “gas barrier layer forming condition”, the forming VUV irradiation conditions of the first gas barrier layer and the second gas barrier layer are shown, and in this example, the forming conditions of the first gas barrier layer and the second gas barrier layer were the same.

TABLE 1-1

| | | | Configuration of intermediate layer | | | |
|---|---|---|---|---|---|---|
| | | Film | | | Particle | |
| | | thickness of | | | diameter of | |
| | | first gas | | | hydrophilic | Shape of |
| | | barrier layer | | Constituent material | particle | hydrophilic |
| | Substrate | (nm) | Type | (% by mass) | (nm) | particle |
| Example | (a) | 100 | (ML1) | Hydrophilic metal | 10-20 | Sphere shape |
| 1-1 | | | | compound particle | | |
| | | | | (colloidal silica 1)/ | | |
| | | | | hydrophobic | | |
| | | | | material/surfactant | | |
| | | | | 80.0/19.8/0.2 | | |
| Example | (a) | 100 | (ML2) | Hydrophilic metal | 80-120 | Bead shape |
| 1-2 | | | | compound particle | | |
| | | | | (colloidal silica 2)/ | | |
| | | | | hydrophobic | | |
| | | | | material/surfactant | | |
| | | | | 80.0/19.8/0.2 | | |
| Example | (a) | 100 | (ML3) | Hydrophilic metal | 80-120 | Bead shape |
| 1-3 | | | | compound particle | | |
| | | | | (colloidal silica 2)/ | | |
| | | | | hydrophobic | | |
| | | | | material/surfactant | | |
| | | | | 70.0/29.8/0.2 | | |
| Example | (a) | 100 | (ML4) | Hydrophilic metal | 10-20 | Sphere shape |
| 1-4 | | | | compound particle | | |
| | | | | (colloidal silica 1)/ | | |
| | | | | hydrophobic metal | | |
| | | | | compound particle | | |
| | | | | (siloxane) | | |
| | | | | 80.0/20.0 | | |
| Example | (a) | 100 | (ML5) | Hydrophilic metal | 10-20 | Sphere shape |
| 1-5 | | | | compound particle | | |
| | | | | (colloidal silica 1)/ | | |
| | | | | hydrophobic metal | | |
| | | | | compound particle | | |
| | | | | (siloxane) | | |
| | | | | 94.3/5.7 | | |
| Example | (a) | 100 | (ML6) | Hydrophobic metal | — | — |
| 1-6 | | | | compound particle | | |
| | | | | (silsesquioxane 1) | | |
| | | | | 100 | | |
| Example | (a) | 100 | (ML7) | Hydrophobic metal | — | — |
| 1-7 | | | | compound particle | | |
| | | | | (silsesquioxane 1)/ | | |
| | | | | hydrophobic metal | | |
| | | | | compound particle | | |
| | | | | (silsesquioxane 2) | | |
| | | | | 70/30 | | |

| | Configuration of | | | | | | |
|---|---|---|---|---|---|---|---|
| | intermediate layer | | | | | | Evaluation |
| | Particle | | Film | Gas barrier layer forming condition | | | of water |
| | diameter of | Surface | thickness of | | Temperature | Integrated | vapor |
| | hydrophobic | roughness | second gas | Oxygen | of sample | irradiation | barrier |
| | particle | Rz | barrier layer | concentration | stage | energy | property |
| | (nm) | (nm) | (nm) | (%) | (° C.) | (mJ/cm²) | (hr) |
| Example | — | 80 | 100 | 0.1 | 80 | 3000 | 900 |
| 1-1 | | | | | | | |
| Example | — | 120 | 100 | 0.1 | 80 | 3000 | 1200 |
| 1-2 | | | | | | | |
| Example | — | 55 | 100 | 0.1 | 80 | 3000 | 1200 |
| 1-3 | | | | | | | |
| Example | 15 | 41 | 100 | 0.1 | 80 | 3000 | 1450 |
| 1-4 | | | | | | | |
| Example | 12 | 38 | 100 | 0.1 | 80 | 3000 | 1600 |
| 1-5 | | | | | | | |
| Example | 20 | 45 | 100 | 0.1 | 80 | 3000 | 1800 |
| 1-6 | | | | | | | |
| Example | 20/14 | 40 | 100 | 0.1 | 80 | 3000 | 2200 |
| 1-7 | | | | | | | |

TABLE 1-2

| | | | Configuration of intermediate layer | | | |
|---|---|---|---|---|---|---|
| | | Film | | | Particle | |
| | | thickness of | | | diameter of | |
| | | first gas | | | hydrophilic | Shape of |
| | | barrier layer | | Constituent material | particle | hydrophilic |
| | Substrate | (nm) | Type | (% by mass) | (nm) | particle |
| Example | (b) | 100 | (ML6) | Hydrophobic metal | — | — |
| 1-8 | | | | compound particle | | |
| | | | | (silsesquioxane 1) | | |
| | | | | 100 | | |
| Example | (c) | 100 | (ML4) | Hydrophilic metal | 10-20 | Sphere shape |
| 1-9 | | | | compound particle | | |
| | | | | (colloidal silica 1)/ | | |
| | | | | hydrophobic metal | | |
| | | | | compound particle | | |
| | | | | (siloxane) | | |
| | | | | 80.0/20.0 | | |
| Example | (d) | 100 | (ML6) | Hydrophobic metal | — | — |
| 1-10 | | | | compound particle | | |
| | | | | (silsesquioxane 1) | | |
| | | | | 100 | | |
| Comparative | (b) | 100 | None | — | — | — |
| Example | | | | | | |
| 1-1 | | | | | | |
| Comparative | (a) | 100 | None | — | — | — |
| Example | | | | | | |
| 1-2 | | | | | | |
| Comparative | (a) | 100 | None | — | — | — |
| Example | | | | | | |
| 1-3 | | | | | | |
| Comparative | (a) | 100 | (ML8) | Hydrophilic metal | 10-20 | Sphere shape |
| Example | | | | compound particle | | |
| 1-4 | | | | (colloidal silica 1)/ | | |
| | | | | 100 | | |
| Comparative | (a) | 100 | (ML9) | Hydrophilic metal | 10-20 | Sphere shape |
| Example | | | | compound particle | | |
| 1-5 | | | | (colloidal silica 3)/ | | |
| | | | | 60.0/39.8/0.2 | | |

| | Configuration of | | | | | | |
|---|---|---|---|---|---|---|---|
| | intermediate layer | | | | | | Evaluation |
| | Particle | | Film | Gas barrier layer forming condition | | | of water |
| | diameter of | Surface | thickness of | | Temperature | Integrated | vapor |
| | hydrophobic | roughness | second gas | Oxygen | of sample | irradiation | barrier |
| | particle | Rz | barrier layer | concentration | stage | energy | property |
| | (nm) | (nm) | (nm) | (%) | (° C.) | (mJ/cm²) | (hr) |
| Example | 20 | 45 | 100 | 0.1 | 80 | 3000 | 1800 |
| 1-8 | | | | | | | |
| Example | 15 | 41 | 100 | 0.1 | 80 | 3000 | 1700 |
| 1-9 | | | | | | | |
| Example | 20 | 45 | 100 | 0.1 | 80 | 3000 | 1800 |
| 1-10 | | | | | | | |
| Comparative | — | None | 100 | 0.1 | 80 | 3000 | 400 |
| Example | | | | | | | |
| 1-1 | | | | | | | |
| Comparative | — | None | 100 | 0.1 | 80 | 3000 | 200 |
| Example | | | | | | | |
| 1-2 | | | | | | | |
| Comparative | — | None | 100 | 0.1 | 80 | 4500 | 180 |
| Example | | | | | | | |
| 1-3 | | | | | | | |
| Comparative | — | 25 | 100 | 0.1 | 80 | 3000 | 180 |
| Example | | | | | | | |
| 1-4 | | | | | | | |
| Comparative | — | 78 | 100 | 0.1 | 80 | 3000 | 120 |
| Example | | | | | | | |
| 1-5 | | | | | | | |

As shown in Tables 1-1 and 1-2, by the use of the gas barrier films of the present invention, the time when the area corresponding to corroded metal calcium exceeds 20% was long, that is, not less than 900 hours. Meanwhile, by the use of the gas barrier films of comparative examples, such a result was obtained that the time was not more than 400 hours. Accordingly, it was found that the gas barrier films of the present invention can maintain an extremely high barrier property over a long period of time, and have good durability.

In particular, by the use of the gas barrier films of Examples 1-7, the time when the area corresponding to corroded metal calcium exceeded 20% was not less than 2,000 hours. Accordingly, in at least examples, it was shown that the gas barrier film equipped with the intermediate layer ML7 (formed by using two kinds of hydrophobic metal compound particles) had particularly good durability.

<<Evaluation of Heat Resistance of Gas Barrier Film>>

The gas barrier films manufactured above in Examples 1-1 to 1-10 and Comparative Examples 1-1 to 1-5 were subjected to heating treatment under an air atmosphere for 10 min at 220° C. At that time, each of the gas barrier layer surfaces of the gas barrier films was kept from being in contact with members. After the heating treatment, the gas barrier films were extracted into an atmosphere at room temperature and cooled to room temperature as they are. Subsequently, in the same manner as the evaluation of water vapor barrier property as Evaluation 1, evaluation of the water vapor barrier property was performed. The results are shown in Table 2. In each Example, the evaluation results were also good like those without having heating treatment. Accordingly, it was found that the gas barrier films of the present invention have excellent heat resistance, can maintain an extremely high barrier property for a long period of time, and have good durability.

TABLE 2

| | Evaluation of gas barrier property | |
|---|---|---|
| | Before heating | After heating |
| | (hr) | (hr) |
| Example 1-1 | 900 | 870 |
| Example 1-2 | 1200 | 1100 |
| Example 1-3 | 1200 | 1150 |
| Example 1-4 | 1450 | 1250 |
| Example 1-5 | 1600 | 1560 |
| Example 1-6 | 1800 | 1750 |
| Example 1-7 | 2200 | 2160 |
| Example 1-8 | 1800 | 1740 |
| Example 1-9 | 1700 | 1660 |
| Example 1-10 | 1800 | 1770 |
| Comparative | 400 | 210 |
| Example 1-1 | | |
| Comparative | 200 | 50 |
| Example 1-2 | | |
| Comparative | 180 | 90 |
| Example 1-3 | | |
| Comparative | 180 | 90 |
| Example 1-4 | | |
| Comparative | 120 | 45 |
| Example 1-5 | | |

### Evaluation 2: Evaluation of Durability of Electronic Device Using Gas Barrier Film

### <<Manufacture of Organic Thin Layer Electronic Device>>

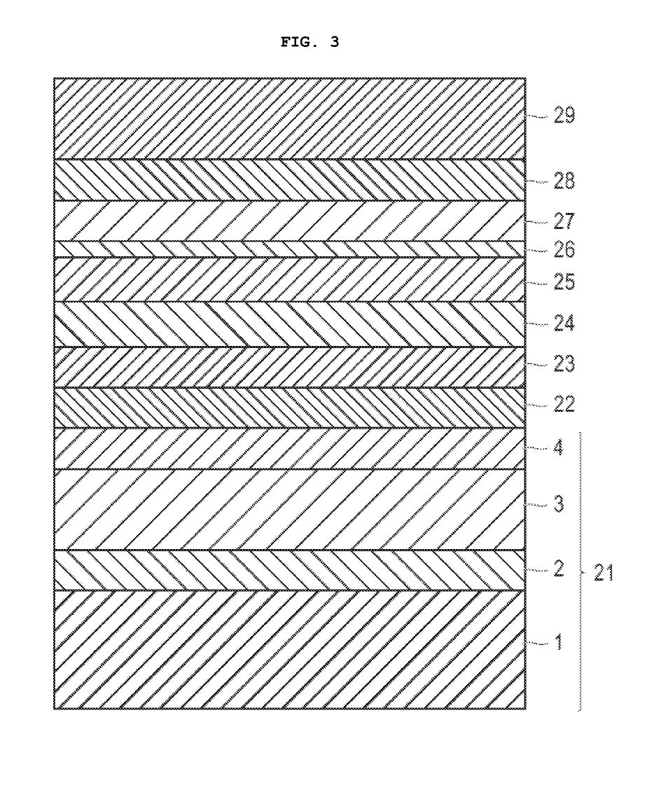

By using the gas barrier films manufactured in Examples 1-1 to 1-3 and 1-7 and Comparative Examples 1-3 to 1-5 as sealing films, each of the organic EL elements (Examples 2-1 to 2-4 and Comparative Examples 2-1 to 2-3) as an organic thin layer electronic device shown in FIG. 3 was fabricated. The gas barrier films used herein are shown in Table 3.

[Manufacture of Organic EL Element]

(Formation of First Electrode Layer 22)

On the gas barrier layer 4 of each gas barrier film 21, ITO (indium tin oxide) film having a thickness of 150 nm was formed by a sputtering method, and patterning is performed by photolithography, whereby a first electrode layer 22 was formed. Meanwhile, the pattern was formed to be a pattern having a light emitting area of 50 mm².

(Formation of Hole Transport Layer 23)

On the top of the first electrode layer 22 of each gas barrier film 21 having the first electrode layer 22 formed thereon, the following coating liquid for hole transport layer formation was coated using an extrusion coater under an environment of 25° C. and at a relative humidity of 50%, and thereafter drying and heating treatment were performed under the following condition, whereby a hole transport layer 23 was formed. The coating liquid for hole transport layer formation was coated such that the thickness after drying was 50 nm.

Before application of the coating liquid for hole transport layer formation, cleaned surface modification treatment for the gas barrier film was performed at irradiation intensity of 15 mW/cm² and distance of 10 mm by using a low pressure mercury lamp having a wavelength of 184.9 nm. The antistatic treatment was performed by using a neutralizer having weak X ray.

<Preparation of Coating Liquid for Hole Transport Layer Formation>

A solution obtained by diluting polyethylene dioxythiophene.polystyrene sulfonate (PEDOT/PSS, Bytron P AI 4083 manufactured by Bayer) to 65% with pure water, 5% with methanol was prepared as a coating liquid for hole transport layer formation.

<Condition for Drying and Heating Treatment>

After application of the coating liquid for hole transport layer formation, the solvent was removed at temperature of 100° C. with air from height of 100 mm, discharge air speed of 1 m/s, and width air speed distribution of 5% toward the formed film surface. Subsequently, by using an apparatus for heating treatment, a heating treatment based on backside electric heating mode was performed at 150° C. to form the hole transport layer 23.

(Formation of Light Emitting Layer 24)

On the top of the hole transport layer 23 formed above, a coating liquid for white light emitting layer formation shown below was coated by using an extrusion coater under the following condition, and thereafter, drying and heating treatment were performed under the following condition, whereby an light emitting layer 24 was formed. The coating liquid for white light emitting layer formation was coated such that the thickness after drying was 40 nm.

<Coating Liquid for White Light Emitting Layer Formation>

1.0 g of a compound as the host material represented by the following chemical formula H-A, 100 mg of a compound as the dopant material represented by the following chemical formula D-A, 0.2 mg of a compound as the dopant material represented by the following chemical formula D-B, and 0.2 mg of a compound as the dopant material represented by the following chemical formula D-C were dissolved in 100 g of toluene to prepare a coating liquid for white light emitting layer formation.

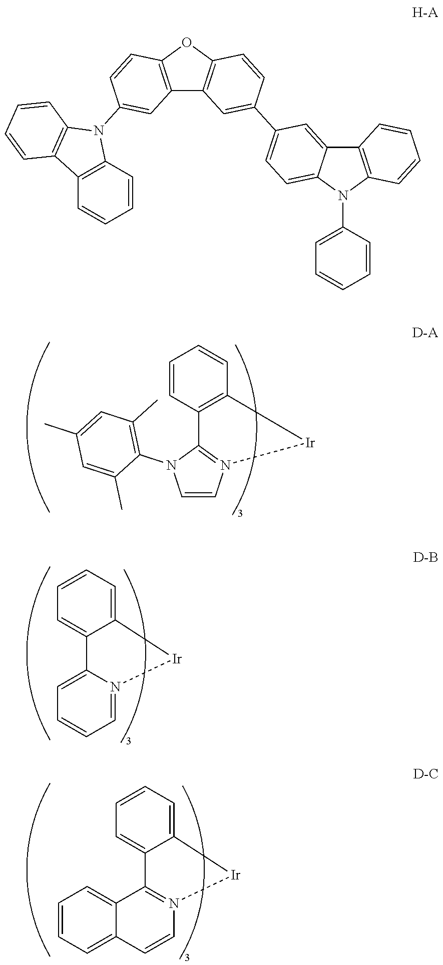

<Coating Condition>

The coating process was performed under an environment with nitrogen gas concentration of 99% or more, temperature of 25° C. and coating speed of 1 m/min.

<Condition for Drying and Heating Treatment>

After applying the coating liquid for forming a white light emitting layer, the solvent was removed at temperature of 60° C. with air from height of 100 mm, discharge air speed of 1 m/s, and width air speed distribution of 5% toward the formed film surface. Subsequently, according to a heating treatment at the temperature of 130° C., the light emitting layer 24 was formed.

(Formation of Electron Transport Layer 25)

The following coating liquid for electron transport layer formation was coated onto the light emitting layer 24 formed above by using an extrusion coater under the following condition, and thereafter, drying and heating treatment were performed under the following condition, whereby an electron transport layer 25 was formed. The coating liquid for electron transport layer formation was coated such that the thickness after drying was 30 nm.

<Coating Condition>

The coating process was performed under an atmosphere with nitrogen gas concentration of 99% or more, and coating temperature of 25° C. and coating speed of 1 m/min for the coating liquid for electron transport layer formation.

<Coating Liquid for Electron Transport Layer Formation>

As for the electron transport layer, a compound represented by the following chemical formula E-A was dissolved in 2,2,3,3-tetrafluoro-1-propanol to obtain a 0.5% by mass solution, which was then used as the coating liquid for electron transport layer formation.

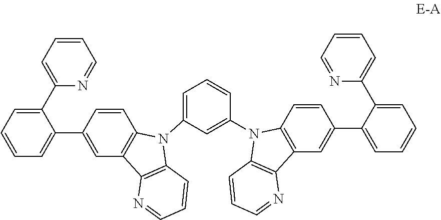 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Condition for Drying and Heating Treatment>

After the application of the coating liquid for electron transport layer formation, the solvent was removed at temperature of 60° C. with air from height of 100 mm, discharge air speed of 1 m/s, and width air speed distribution of 5% toward the formed film surface. Subsequently, according to a heating treatment at the temperature of 200° C. in a heating treatment part, the electron transport layer 25 was formed.

(Formation of Electron Injection Layer 26)

An electron injection layer 26 was formed on the top of the formed electron transport layer 25. First, the substrate was loaded into a chamber under reduced pressure, and the pressure was lowered to 5×10⁻⁴ Pa. By heating cesium fluoride which has been prepared in advance in a tantalum deposition boat within a vacuum chamber, an electron injection layer having a thickness of 3 nm was formed.

(Formation of Second Electrode 27)

On the electron injection layer 26 formed above and, at the same time, at a portion other than a portion which is an extraction electrode of a first electrode 22, a mask pattern film was formed to have a light emitting area of 50 mm² by using aluminum as a material for second electrode formation under vacuum of 5×10⁻⁴ Pa and vapor deposition method to have an extraction electrode, and as a result, a second electrode 27 having a thickness of 100 nm was layered.

(Cutting)

As described above, each laminate formed up to the second electrode 27 was transferred again to a nitrogen atmosphere, and cut to a predetermined size by using ultraviolet laser to manufacture an organic EL element.

(Attachment of Electrode Lead)

To the manufactured organic EL element, a flexible print substrate (base film: polyimide 12.5 μm, pressed copper foil 18 μm, cover layer: polyimide 12.5 μm, surface treatment: NiAu plating) was attached by using an anisotropic conductive film DP3232S9 manufactured by Sony Chemical and Information Device Corporation.

Compression condition: compression was performed for 10 seconds at temperature of 170° C. (ACF temperature of 140° C. measured by using a separate thermocouple) and pressure of 2 MPa.

(Sealing)

As a sealing member 29, a 30-μm thick aluminum foil (manufactured by TOYO ALUMINIUM K.K.) laminated with a polyethylene terephthalate (PET) film (12-μm thick) by using adhesive for dry lamination (two-liquid reaction type urethane-based adhesive) was provided (thickness of adhesive layer: 1.5 μm).

A thermosetting adhesive was uniformly coated on an aluminum surface of the provided sealing member 29 to have a thickness of 20 μm along the surface attached with an aluminum foil (glossy surface) by using a dispenser, and an adhesive layer 28 was formed.

At this time, as the thermosetting adhesive, the following epoxy-based adhesive containing the following components was used.

Bisphenol A diglycidyl ether (DGEBA), Dicyandiamide (DICY), and Epoxy adduct-based curing promoter.

The sealing member 29 was closely attached and placed such that a joint portion between the extraction electrode and the electrode lead is covered. Then, it was tightly sealed by using a compression roll with compression condition including compression roll temperature of 120° C., pressure of 0.5 MPa, and apparatus speed of 0.3 m/min.

<<Evaluation of Organic EL Element>>

The organic EL elements (Examples 2-1 to 2-4 and Comparative Examples 2-1 to 2-3) manufactured above were subjected to durability evaluation according to the following method.

[Durability Evaluation]

(Accelerated Deterioration Treatment)

Each organic EL element manufactured above was subjected to an accelerated deterioration treatment for 400 hours under environments of 60° C. and 90% RH, and under environments of 85° C. and 85%. Thereafter, together with an organic EL element not treated with an accelerated deterioration treatment, an evaluation of dark spots was performed as follows.

(Evaluation of Dark Spots)

Each of the organic EL element after the accelerated deterioration treatment and the organic EL element not treated with the accelerated deterioration treatment was applied with electric current of 1 mA/cm². After continuous light emission for 24 hours, a part of the panel was enlarged by using 100× microscope (MS-804 manufactured by SCHOTT MORITEX CORPORATION, lens: MP-ZE25-200), and a photographic image was taken. After cutting the photographed image to a 2-mm square, the ratio of an area having dark spots was obtained and the ratio of resistance to element deterioration was calculated according to the following formula. The durability was then evaluated according to the following criteria. When the evaluated rank is ⊙ or ◯, it was determined as a practically preferable one.

Resistance to element deterioration=(Area of dark spots occurred in an element not treated with accelerated deterioration treatment/Area of dark spots occurred in an element treated with accelerated deterioration treatment)×100(%)

⊙: Resistance to element deterioration is not less than 90%.
◯: Resistance to element deterioration is not less than 60% and less than 90%.
Δ: Resistance to element deterioration is not less than 20% and less than 60%.
X: Resistance to element deterioration is less than 20%.

The results obtained from above are described in Table 3.

TABLE 3

| | | Evaluation | Evaluation |
|---|---|---|---|
| | | of organic | of organic |
| | | EL | EL |
| | | element | element |
| | Gas barrier | 60° C., | 85° C., |
| Element | film | 90% RH | 85% RH |
| Example 2-1 | Example 1-1 | ⊚ | ⊚ |
| Example 2-2 | Example 1-2 | ⊚ | ⊚ |
| Example 2-3 | Example 1-3 | ⊚ | ⊚ |
| Example 2-4 | Example 1-7 | ⊚ | ⊚ |
| Comparative | Comparative | X | X |
| Example 2-1 | Example 1-3 | | |
| Comparative | Comparative | Δ | X |
| Example 2-2 | Example 1-4 | | |
| Comparative | Comparative | X | X |
| Example 2-3 | Example 1-5 | | |

As clearly shown in the results described in Table 3, in the elements of Examples 2-1 to 2-4 equipped with the gas barrier film of the present invention, the resistance to element deterioration was not less than 90%, and the elements have good durability. Meanwhile, in the elements of Comparative Examples 2-1 to 2-3 equipped with the gas barrier films of Comparative Examples 1-3 to 1-5, the resistance to element deterioration was less than 60%.

Accordingly, the gas barrier films of Examples 1-1 to 1-3 and 1-7 of the present invention have an extremely high gas barrier property enabling use as a sealing film of an organic EL element.

The present application is based on Japanese Patent Application No. 2012-083995 filed on Apr. 2, 2012, and its disclosure is incorporated herein by reference in its entirety.

### REFERENCE SIGNS LIST

1: substrate (support)
2: first gas barrier layer
3: intermediate layer
4: second gas barrier layer
5: bleed out preventing layer
11: apparatus chamber
12: Xe excimer lamp
13: holder of excimer lamp
14: sample stage
15: sample formed with polysilazane coating layer
16: light shielding plate
21: gas barrier film
22: first electrode layer
23: hole transport layer
24: light emitting layer
25: electron transport layer
26: electron injection layer
27: second electrode layer
28: adhesive layer
29: sealing member

1. A gas barrier film comprising:
a substrate;
a first gas barrier layer formed by irradiating a polysilazane-containing layer with a vacuum ultraviolet ray;
a second gas barrier layer formed by irradiating a polysilazane-containing layer with a vacuum ultraviolet ray; and
a hydrophobic intermediate layer disposed between the first gas barrier layer and the second gas barrier layer and containing a metal compound particle.

2. The gas barrier film according to claim 1, wherein the polysilazane-containing layer and the hydrophobic intermediate layer are formed by a coating method.

3. The gas barrier film according to claim 1, wherein the hydrophobic intermediate layer contains 65 to 100% by mass of a metal compound particle (A) having a particle diameter of 1 to 200 nm and 0 to 35% by mass of a hydrophobic material (B), relative to 100% by mass of a total amount of the metal compound particle (A) and the hydrophobic material (B).

4. The gas barrier film according to claim 3, wherein in the hydrophobic intermediate layer,
(I) the metal compound particle (A) is a colloidal silica particle, and a content of the colloidal silica particle is 65 to 99.9% by mass relative to 100% by mass of a total of the colloidal silica particle and the hydrophobic material (B); or
(II) the metal compound particle (A) is a polyorganosiloxane particle or a polyorganosilsesquioxane particle, and a content of the polyorganosiloxane particle or the polyorganosilsesquioxane particle is 65 to 100% by mass relative to 100% by mass of a total content of the polyorganosiloxane particle or the polyorganosilsesquioxane particle and the hydrophobic material (B).

5. The gas barrier film according to claim 4, wherein the colloidal silica particle has a chain shape or a beaded shape.

6. The gas barrier film according to claim 1, wherein the hydrophobic intermediate layer contains at least two or more kinds of hydrophobic metal compound particles.

7. The gas barrier film according to claim 1, wherein surface roughness (Rz) of the hydrophobic intermediate layer is in the range of 1 to 200 nm.

8. An electronic device using the gas barrier film set forth in claim 1.
